(19) United States
(12) Patent Application Publication
(10) Pub. No.: US 2026/0290017 A1
(43) Pub. Date: Sep. 24, 2026

(54) METHOD FOR PREDICTING HUMAN OCCUPANCY AND CAPACITY IN A BUILDING

(71) Applicant: VergeSense, Inc., San Francisco, CA (US)

(72) Inventors: Kelby Green, San Francisco, CA (US); Kanav Dhir, San Francisco, CA (US)

(21) Appl. No.: 19/552,362

(22) Filed: Feb. 27, 2026

Related U.S. Application Data
(60) Provisional application No. 63/764,524, filed on Feb. 27, 2025.

(51) Int. Cl. G06V 20/50

(52) U.S. Cl. CPC G06V 20/50

(57) ABSTRACT

One variation of the method includes: accessing a corpus of sensor data captured by a population of sensor blocks; calculating a total human occupancy count, in a set of total human occupancy counts, during a daily time interval; for each zone type, in a set of zone types, deriving a human occupancy count, in a set of human occupancy counts, within the zone type; and deriving an occupancy distribution function relating human occupancy counts to total human occupancy counts. The method also includes: accessing a predicted total human occupancy count within a target space; based on the occupancy distribution function, generating a predicted distribution of humans occupying the target space; and, in response to a first count of humans, predicted to occupy a first zone type, exceeding a first occupancy capacity of the first zone type, predicting an overcapacity event within the target space during a future daily time interval.

### CROSS-REFERENCE TO RELATED APPLICATIONS

This Application claims the benefit of U.S. Provisional Application No. 63/764,524, filed on 27 Feb. 2025, which is incorporated in its entirety by this reference.

### TECHNICAL FIELD

This invention relates generally to the field of workplace monitoring and, more specifically, to a new and useful method for predicting human occupancy and capacity in a building in the field of workplace monitoring.

### BRIEF DESCRIPTION OF THE FIGURES

FIGS. 1A and 1B are flowchart representations of a method;

FIG. 2 is a flowchart representation of one variation of the method;

FIGS. 3A and 3B are flowchart representations of one variation of the method;

FIG. 4 is a flowchart representation of one variation of the method;

FIG. 5 is a flowchart representation of one variation of the method; and

FIG. 6 is a flowchart representation of one variation of the method.

### DESCRIPTION OF THE EMBODIMENTS

The following description of embodiments of the invention is not intended to limit the invention to these embodiments but rather to enable a person skilled in the art to make and use this invention. Variations, configurations, implementations, example implementations, and examples described herein are optional and are not exclusive to the variations, configurations, implementations, example implementations, and examples they describe. The invention described herein can include any and all permutations of these variations, configurations, implementations, example implementations, and examples.

### 1. Method

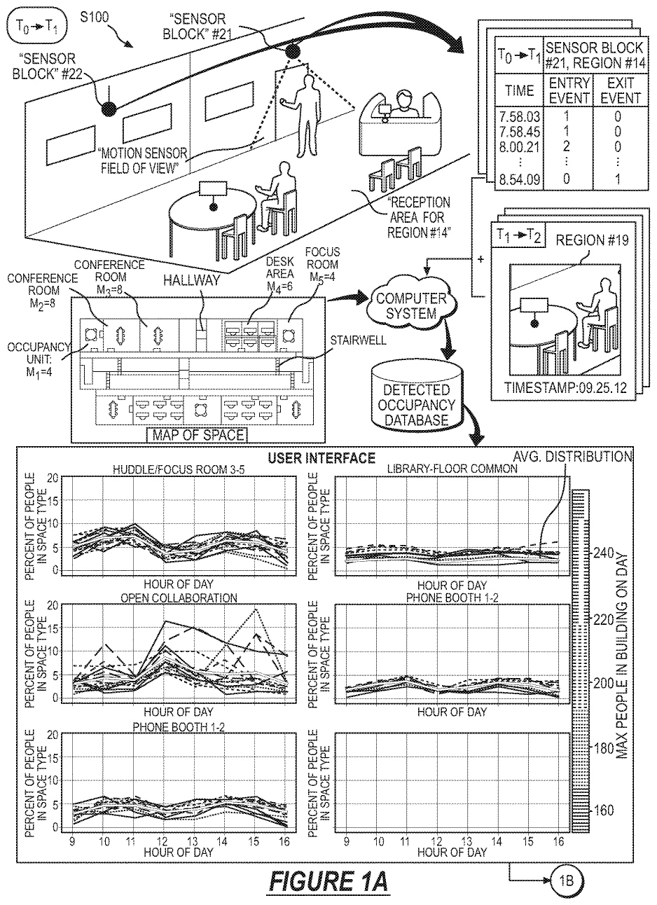

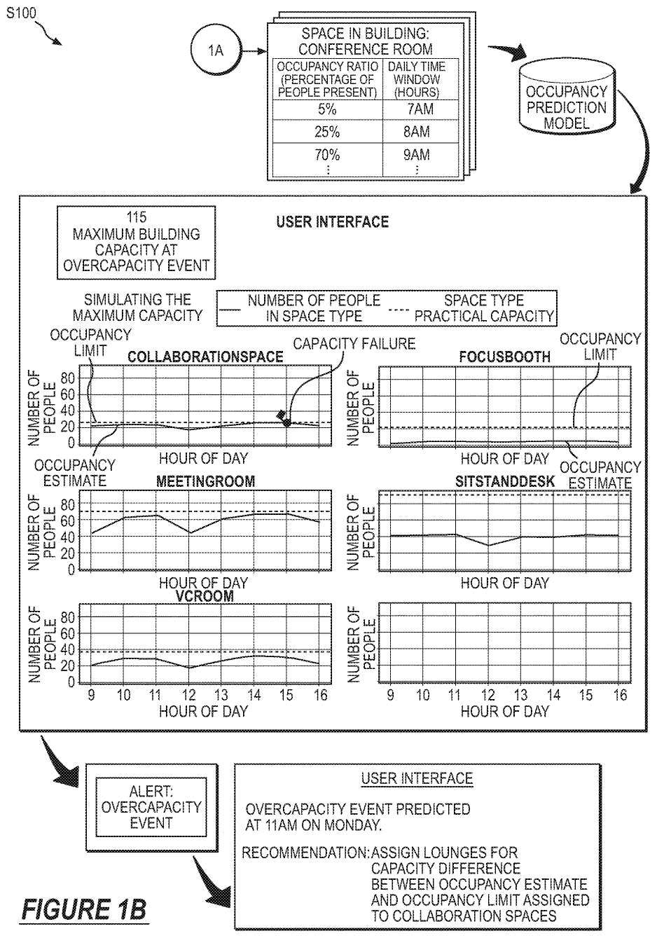

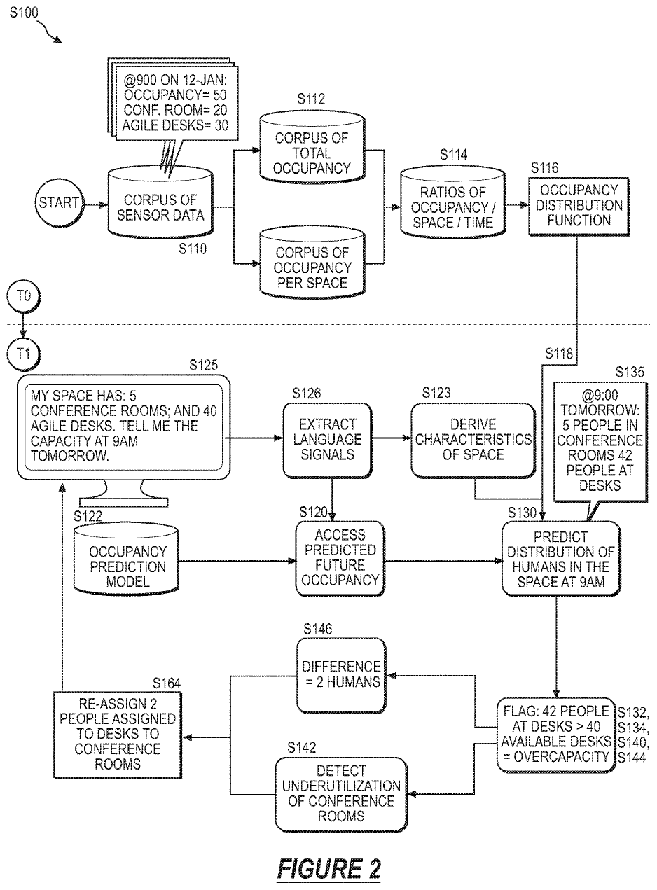

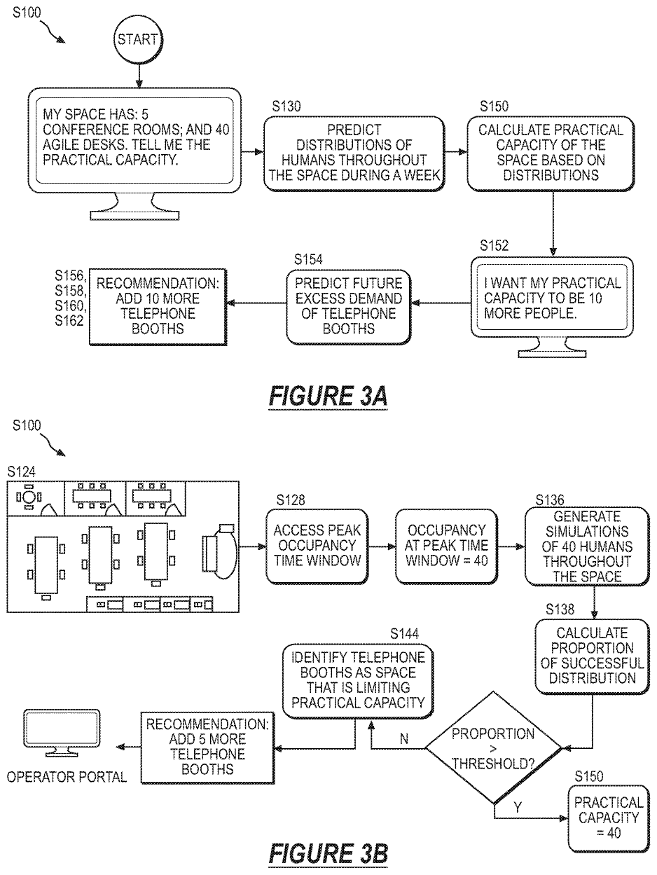

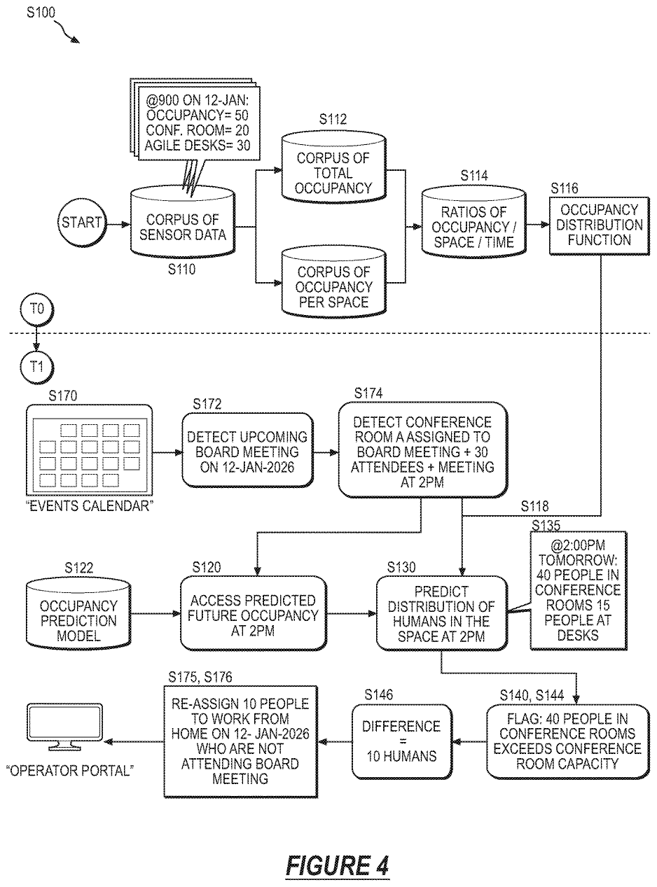

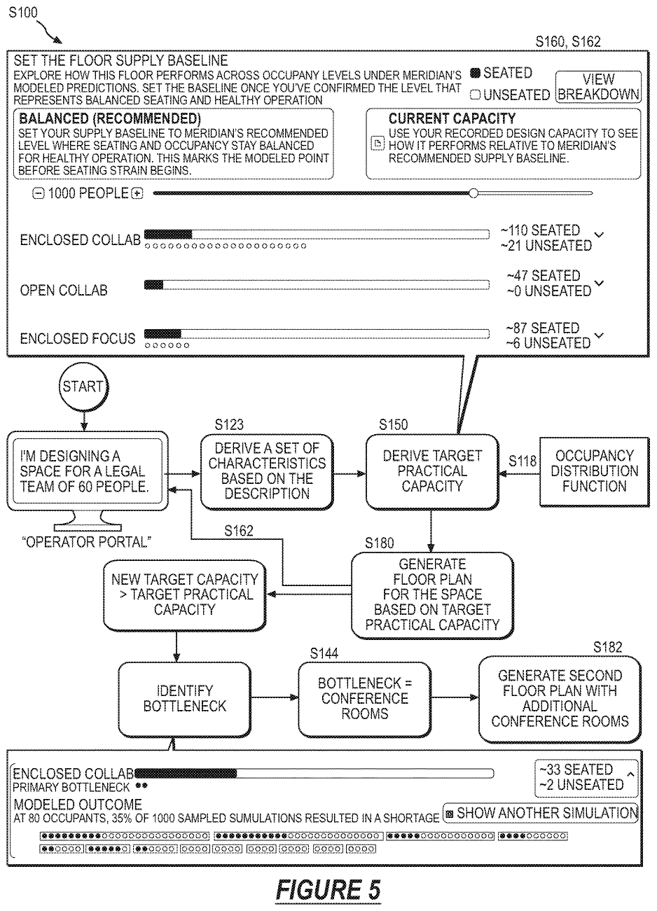

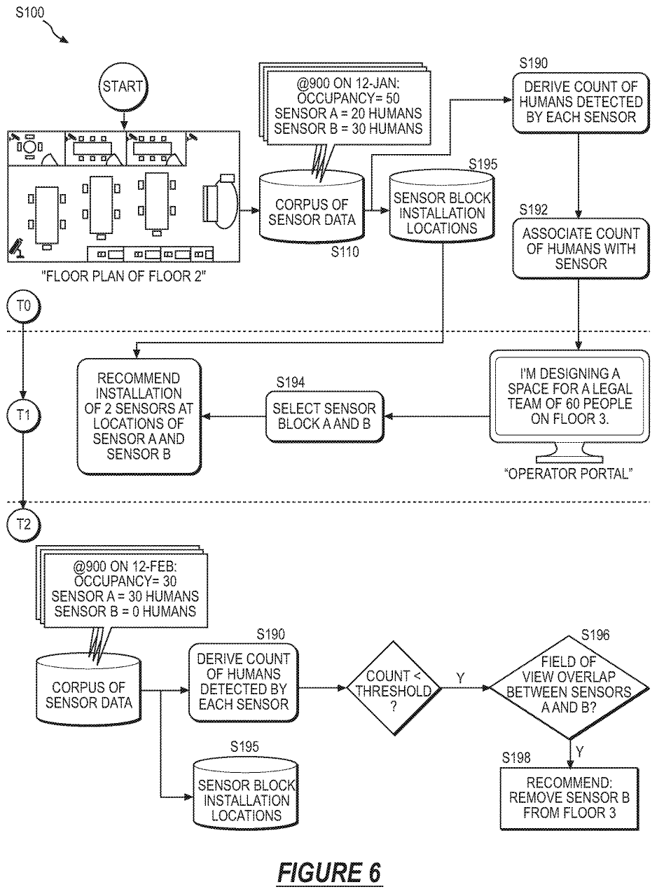

As shown in FIGS. 1-6, a method S100 includes. accessing a corpus of sensor data captured by a population of sensor blocks, distributed throughout a set of spaces, during a first time period in Block S110.

The method S100 also includes, based on the corpus of sensor data, for each space in the set of spaces, and for each daily time interval in a set of daily time intervals: calculating a total human occupancy count, in a set of total human occupancy counts, in the space during the daily time interval in Block S112; and, for each zone type in a set of zone types within the space, deriving a zone-specific human occupancy count, in a set of zone-specific human occupancy counts, within the zone type within the space during the daily time interval in Block S114.

The method S100 further includes, based on the corpus of sensor data, deriving an occupancy distribution function relating zone-specific human occupancy count for each zone type to total human occupancy count within the set of daily time intervals based on the set of total human occupancy counts and the set of zone-specific human occupancy counts in Block S116.

The method S100 further includes, during a second time period succeeding the first time period: accessing a predicted total human occupancy count within a target space during a future daily time interval in Block S120; based on the occupancy distribution function, the predicted total human occupancy count, and the future time interval, generating a predicted distribution of humans occupying the set of zone types within the target space during the future daily time interval, the predicted distribution of humans including a first count of humans predicted to occupy a first zone type, in the set of zone types, within the target space during the future time interval in Block S130; accessing a first occupancy capacity of the first zone type within the target space in Block S132; and, in response to the first count of humans exceeding the first occupancy capacity of the first zone type within the target space, predicting an overcapacity event within the target space during the future daily time interval in Block S140.

### 1.1 Variation: Single-space Training+Overcapacity Event Detection

In one variation, the method S100 includes: accessing a corpus of sensor data captured by a population of sensor blocks, distributed throughout a space, during a first time period in Block S110; based on the corpus of sensor data and for each daily time interval in a set of daily time intervals, calculating a total human occupancy, in a set of total human occupancy counts, in the space during the daily time interval in Block S112; and, for each zone type, in a set of zone types, within the space, deriving a zone-specific human occupancy count, in a set of zone-specific human occupancy counts, within the zone type within the space during the daily time interval in Block S114.

This variation of the method S100 also includes, based on the corpus of sensor data, deriving an occupancy distribution function relating zone-specific human occupancy count for each zone type to total human occupancy count within the set of daily time intervals based on the set of total human occupancy counts and the set of zone-specific human occupancy counts in Block S116.

This variation of the method S100 further includes, during a second time period succeeding the first time period: accessing a predicted total human occupancy count within the space during a future time interval in Block S120; based on the occupancy distribution function, the predicted total human occupancy count, and the future time interval, generating a predicted distribution of humans occupying the set of zone types within the space during the future time interval, the predicted distribution of humans including a first count of humans predicted to occupy a first zone type, in the set of zone types, within the space during the future time interval in Block S130; accessing a first occupancy capacity of the first zone type within the space in Block S132; and, in response to the first count of humans exceeding the first occupancy capacity of the first zone type within the space, predicting an overcapacity event within the space during the future time interval in Block S140.

### 1.2 Variation: Sensor-Less Overcapacity Event Detection

In another variation, the method S100 includes accessing a corpus of occupancy data in Block S110, the corpus of occupancy data representing: a total human occupancy count, in a set of total human occupancy counts, in a representative space during each daily time interval in a set of daily time intervals during a first time period; and a zone-specific human occupancy count, in a set of zone-specific human occupancy counts, for each zone type, in a set of zone types, within the representative space during each daily time interval in the set of daily time intervals during the first time period.

In this variation, the method S100 also includes, based on the corpus of occupancy data, deriving an occupancy distribution function relating zone-specific human occupancy count for each zone type to total human occupancy count within the set of daily time intervals based on the set of total human occupancy counts and the set of zone-specific human occupancy counts in Block S116.

In this variation, the method S100 further includes, during a second time period succeeding the first time period: accessing a predicted total human occupancy count within a target space during a future time interval in Block S120; based on the occupancy distribution function, the predicted total human occupancy count, and the future time interval, generating a predicted distribution of humans occupying the set of zone types within the target space during the future time interval, the predicted distribution of humans including a first count of humans predicted to occupy a first zone type, in the set of zone types, within the target space during the future time interval in Block S130; accessing a first occupancy capacity of the first zone type within the target space in Block S132; and, in response to the first count of humans exceeding the first occupancy capacity of the first zone type within the target space, predicting an overcapacity event within the target space during the future time interval in Block S140.

### 1.3 Variation: Practical Capacity

In another variation, the method S100 includes accessing a corpus of sensor data captured by a population of sensor blocks, distributed throughout a set of spaces, during a first time period in Block S110 and, based on the corpus of sensor data and for each space in the set of spaces: calculating a total human occupancy, in a set of total human occupancy counts, in the space during the first time period in Block S112; and, for each zone type, in a set of zone types, within the space, deriving a zone-specific human occupancy count, in a set of zone-specific human occupancy counts, within the zone type within the space during the first time period in Block S114.

This variation of the method S100 also includes, based on the corpus of sensor data, deriving an occupancy distribution function relating zone-specific human occupancy counts for each zone type to total human occupancy counts based on the set of total human occupancy counts and the set of zone-specific human occupancy counts in Block S116.

This variation of the method S100 further includes, during a second time period succeeding the first time period: accessing a first occupancy capacity of a first zone type, in the set of zone types, within a target space in Block S132; and accessing a second occupancy capacity of a second zone type, in the set of zone types, within the target space in Block S132.

This variation of the method S100 also includes, based on the occupancy distribution function: calculating a first maximum total human occupancy count, within the target space, predicted to yield a first count of humans, occupying the first zone type within the target space, equal to the first occupancy capacity of the first zone type within the target space in Block S134; and calculating a second maximum total human occupancy count, within the target space, predicted to yield a second count of humans, occupying the second zone type within the target space, equal to the second occupancy capacity of the second zone type within the target space in Block S134.

This variation of the method S100 further includes, in response to the first maximum total human occupancy count falling below the second maximum total human occupancy count, recording the first maximum total human occupancy count as a practical capacity of the target space in Block S150.

### 1.4 Variation: Time-agnostic Practical Capacity

In yet another variation, the method S100 includes: accessing a corpus of sensor data captured by a population of sensor blocks, distributed throughout a set of spaces, during a first time period in Block S110; based on the corpus of sensor data and for each space in the set of spaces, calculating a total human occupancy, in a set of total human occupancy counts, in the space during the first time period in Block S112; based on the corpus of sensor data and for each space in the set of spaces, and for each zone type in a set of zone types within the space, deriving a zone-specific human occupancy count, in a set of zone-specific human occupancy counts, within the zone type within the space during the first time period in Block S114; and deriving an occupancy distribution function relating zone-specific human occupancy counts for each zone type to total human occupancy counts based on the set of total human occupancy counts and the set of zone-specific human occupancy counts in Block S116.

This variation of the method S100 also includes, during a second time period succeeding the first time period: accessing a first occupancy capacity of a first zone type, in the set of zone types, within a target space in Block S132; and accessing a second occupancy capacity of a second zone type, in the set of zone types, within the target space in Block S156.

This variation of the method S100 further includes, based on the occupancy distribution function: calculating a first maximum total human occupancy count, within the target space, predicted to yield a first count of humans, occupying the first zone type within the target space, equal to the first occupancy capacity of the first zone type within the target space in Block S134; calculating a second maximum total human occupancy count, within the target space, predicted to yield a second count of humans, occupying the second zone type within the target space, equal to the second occupancy capacity of the second zone type within the target space in Block S134; and, in response to the first maximum total human occupancy count falling below the second maximum total human occupancy count, recording the first maximum total human occupancy count as a practical capacity of the target space in Block S150.

### 1.5 Variation: Time-interval Dependent Practical Capacity

In yet another variation, the method S100 includes: accessing a corpus of sensor data captured by a population of sensor blocks, distributed throughout a set of spaces, during a first time period in Block S110; based on the corpus of sensor data, for each space in the set of spaces, and for each daily time interval in a set of daily time intervals, calculating a total human occupancy, in a set of total human occupancy counts, in the space during the daily time interval in Block S112; for each zone type in a set of zone types within the space, deriving a zone-specific human occupancy count, in a set of zone-specific human occupancy counts, within the zone type within the space during the daily time interval in Block S114; and deriving an occupancy distribution function relating zone-specific human occupancy count for each zone type to total human occupancy count within the set of daily time intervals based on the set of total human occupancy counts and the set of zone-specific human occupancy counts in Block S116.

This variation of the method S100 also includes, during a second time period succeeding the first time period: accessing a first occupancy capacity of a first zone type, in the set of zone types, within a target space in Block S132; accessing a second occupancy capacity of a second zone type, in the set of zone types, within the target space in Block S132; based on the occupancy distribution function, calculating a first set of maximum total human occupancy counts, within the target space, predicted to yield counts of humans, occupying the first zone type within the target space, equal to the first occupancy capacity of the first zone type within the target space during the set of daily time intervals in Block S134; based on the occupancy distribution function, calculating a second set of maximum total human occupancy counts, within the target space, predicted to yield counts of humans, occupying the second zone type within the target space, equal to the second occupancy capacity of the second zone type within the target space during the set of daily time intervals in Block S134; and, based on the first set of maximum total human occupancy counts and the second set of maximum total human occupancy counts, detecting a first daily time interval, in the set of daily time intervals, during which the first zone type limits practical capacity of the target space and detecting a second daily time interval, in the set of daily time intervals, during which the second zone type limits practical capacity of the target space in Block S150.

### 1.6 Variation: Motion Event-Based Occupancy Prediction

Another variation of the method S100 for predicting capacity of a building includes, during a setup period: accessing a corpus of motion events, annotated with timestamps and representing movement of humans within a set of spaces within the building within a set of daily time windows, from a population of sensor blocks; accessing a corpus of detected occupancy (hereinafter “occupancy”) from the population of sensor blocks within the set of daily time windows, each detected occupancy representing a quantity of humans present in a corresponding space, in the set of spaces, within the building; deriving a total occupancy representing a total quantity of humans present in the building based on the corpus of motion events within the set of daily time windows; deriving a ratio of occupancy in each space, in the set of spaces, within the building relative to the total occupancy within each daily time window in the set of daily time windows; and deriving a function relating total occupancies within the building across the set of daily time windows.

The method S100 further includes: at a current time window on a current day, accessing a current total occupancy within the building; calculating an occupancy estimate of each space, in the set of spaces, within the building during a subsequent time window on the current day according to the function; accessing a set of occupancy capacities assigned to each zone type, in the set of zone types, in the target space within the building; and, in response to a particular occupancy estimate for a particular space, in the set of spaces, within the building during the subsequent time window on the current day exceeding a particular occupancy capacity assigned to the particular space, generating an alert to preemptively address excess demand of the particular space in the subsequent time window.

### 1.7 Variation: Long-Term Occupancy+Space Recommendation

One variation of the method S100 includes, during a setup period: accessing a corpus of motion events, annotated with timestamps and representing movement of humans within a set of spaces within the building within a set of daily time windows, from a population of sensor blocks; accessing a corpus of detected occupancy from the population of sensor blocks within the set of daily time windows, each detected occupancy representing a quantity of humans present in a corresponding space, in the set of spaces, within the building; deriving a total occupancy representing a total quantity of humans present in the building based on the corpus of motion events within the set of daily time windows; and deriving a set of ratios of detected occupancy in the set of spaces within the building relative to the total occupancy within the set of daily time windows.

This variation of the method S100 further includes: receiving a target total occupancy for the building from a user; detecting a peak time window associated with a greatest total occupancy within the building; based on the set of ratios and the target total occupancy, calculating an occupancy estimate of each space, in the set of spaces, within the building during the peak time window; and, in response to a particular occupancy estimate for a particular space, in the set of spaces, in the building exceeding a particular occupancy capacity assigned to the particular space, calculating a difference between the particular occupancy estimate and the particular occupancy capacity.

This variation of the method S100 further includes: generating a recommendation to expand the particular space by the difference to support the target total occupancy for the building; and serving the recommendation to the user.

### 2. Applications

Generally, Blocks of the method S100 can be executed by a computer system (e.g., a remote server): to access sensor data representing locations of humans in a set of spaces (e.g., a workplace including conference rooms, agile desks, telephone booths, lounge spaces, etc.) throughout a set of daily time windows; to derive patterns and/or occupancy distributions of humans in the set of spaces throughout the set of daily time windows (i.e., counts of humans occupying each zone type in a set of zone types for the set of spaces) based on this sensor data; and to calculate a practical capacity of a target space based on these patterns and/or occupancy distributions, the practical capacity representing a maximum capacity of the target space at which failure (e.g., exhaustion of a zone type) occurs less than a threshold failure percentage (e.g., 3.5%).

In particular, the computer system can execute Blocks of the method S100 to: predict a future distribution of humans throughout the target space, such as based on the practical capacity of the space; predict an overcapacity event responsive to predicting overcapacity of a particular zone type in the target space according to the future distribution of humans throughout the target space; and notify an administrator of the predicted overcapacity event prior to the future time window to enable the administrator to preemptively mitigate distribution of the humans—such as during a time window immediately prior to the future time window—and prevent the overcapacity event.

In one implementation, the computer system can execute Blocks of the method S100: to access historical sensor data captured by a population of sensor blocks over a set of daily time windows (e.g., 9 AM to 10 AM, 1 PM to 3 PM) for a particular space; to derive historical distribution of humans throughout the particular space based on this historical sensor data; to derive an occupancy distribution function configured to predict distribution of humans throughout the particular space for future time windows based on historical distribution of humans throughout the particular space (and/or a predicted occupancy of the space for the future time windows); to access a target future time window (e.g., input by an administrator); to generate a predicted distribution of humans throughout the particular space for the target future time window based on the occupancy distribution function; and to predict overcapacity events (e.g., excess demand of a particular zone type within the particular space, such as conference rooms or telephone booths) for the target future time window based on the predicted distribution of humans throughout the particular space.

The computer system can then notify an administrator of such overcapacity events prior to the future time window to enable the administrator to preemptively address such overcapacity events, thereby preventing future workplace friction due to lack of desired zone types.

For example, the computer system can: predict an overcapacity event for a first zone type, such as a telephone booth, based on the predicted distribution of humans throughout the particular space for the target future time window; predict future availability of a second zone type, such as a conference room, for the particular space for the target future time window; and recommend future assignment of humans-who would have otherwise desired to occupy a phone booth during the future time window-to these open conference rooms.

Therefore, by predicting distributions of humans throughout a space across future time windows, the computer system can support use of the space according to space-type availability rather than aggregate occupancy alone. Furthermore, the computer system can recommend occupant assignment to thereby enable occupants to access required zone types during normal operation, reduce administrator intervention responsive to space-type exhaustion, and inform planning of zone types and space counts based on how humans occupy the space over time.

Additionally, the computer system can calculate practical capacity for each daily time interval to reflect temporal variation in zone-specific human occupancy relative to occupancy capacities of the zone types. Thus, because practical capacity of the target space dynamically changes throughout the day in response to dynamic human work patterns, the computer system can calculate dynamic practical capacities across daily time intervals rather than remaining fixed and based on aggregate seat count or static building design.

### 2.1 Simulations of Distribution

In one implementation, the computer system can simulate distributions of humans throughout the space during a set of future time windows to calculate practical capacity of the space.

In particular, the computer system can generate a corpus (e.g., 1000 s) of simulations representing simulated distributions of humans throughout the space, such as based on the occupancy distribution function; calculate a proportion of successful distributions of humans based on the corpus of simulations; and, in response to the proportion of successful distributions of humans exceeding a threshold proportion (e.g., 97%), calculate a practical capacity of a target space based on the corpus of simulations.

Therefore, although sufficient total seating may remain available across the target space, simulated assignment may exceed the available quantity or capacity of a particular zone type, such that simulated humans require meeting spaces that cannot be accommodated. The computer system can classify this simulation as an overcapacity event despite total occupancy remaining below a nominal capacity, thereby attributing the failure to a specific space-type limitation rather than to aggregate headcount.

### 2.2 Space Design+Refine

In one implementation, the computer system can recommend space changes and/or space designs to accommodate a target practical capacity for a target space. In particular, the computer system can: identify overutilization of a particular zone type, in the particular target space; and recommend expansion of these spaces and/or addition of spaces of the particular zone type to the target space.

For example, the computer system can recommend addition of a particular zone type to the target space responsive to predicting excess demand for the particular zone type at occupancy levels between the practical capacity and the target practical capacity. In particular, the computer system can recommend transformation of an existing space from a first zone type to a second zone type responsive to predicted underutilization of the first zone type and predicted overcapacity of the second zone type. In the foregoing example, the computer system can derive recommendations from predicted distributions of humans throughout the target space and occupancy capacities associated with individual zone types, as described herein.

In another example, the computer system can iteratively generate recommendations to refine a spatial representation of the target space, such as during design of a target space. The computer system can modify the spatial representation according to a recommended refinement, reevaluate practical capacity of the modified spatial representation, and compare the reevaluated practical capacity to the target practical capacity. The computer system can repeat this process to identify a refinement that yields a practical capacity that satisfies the target practical capacity under expected occupancy distributions.

Therefore, by relating practical capacity and predicted occupancy distributions to space-type constraints, the computer system can recommend refinements to a target space that are grounded in observed and expected use of the spaces rather than nominal capacity assumptions, such that refinements to the target space are driven by how humans occupy the space over time and by which zone types limit usability under target occupancy conditions.

### 2.3 Examples

In one example, the computer system can derive an occupancy distribution function for a target space based on historical occupancy observed across a workday, a work week, and/or a work year. In particular, during a given workday, the computer system can detect humans distributed throughout zone types of the target space at different times of day, such as exhibiting increased use of individual workspaces during morning time windows, increased use of enclosed meeting spaces during mid-day time windows, and increased use of shared or informal spaces during late-afternoon time windows. Throughout a set of daily time windows, the computer system can detect and record distributions of humans across the target space based on sensor data and can calculate, for each time window and for each zone type, in a set of zone types, within the space, deriving a zone-specific human occupancy count, in a set of zone-specific human occupancy counts, within the zone type within the space during the daily time interval relative to total human occupancy counts. The computer system can aggregate these zone-specific human occupancy counts across the set of daily time windows to define an occupancy distribution function representing expected distributions of humans throughout zones of the target space over time.

Then, the computer system can apply the occupancy distribution function to calculate a practical capacity of the target space and/or predict future overcapacity events. For instance, the computer system can assign a candidate total occupancy value to the target space and apply the occupancy distribution function to distribute simulated humans across zone types during a particular time window. The computer system can then compare simulated occupancies of each zone type to corresponding occupancy capacities to derive whether occupancy conditions result in unavailability of one or more zone types. By evaluating multiple candidate total occupancy values, the computer system can calculate a practical capacity representing a maximum total human occupancy count at which such unavailability occurs less than a threshold proportion (e.g., 3.5%) of the time.

In the foregoing example, the computer system can apply the occupancy distribution function to identify a zone type associated with limitation of the target space at the practical capacity. In particular, when occupancy conditions approach or exceed the practical capacity, the computer system can derive an identified zone type that is first associated with predicted overcapacity events, such as by detecting that predicted demand for enclosed meeting spaces exceeds corresponding occupancy capacities while predicted demand for other zone types remains within their occupancy capacities. The computer system can thus attribute limitation of the target space under expected occupancy conditions to the identified zone type. The computer system can then recommend assignment of humans desiring to occupy this zone type to a secondary zone type within the target space, to a work-from-home setup, to a separate floor, or to a separate building to enable these humans to occupy a desired zone type.

In another example, the computer system can apply the occupancy distribution function to support design of a new space. For instance, an administrator may provide a set of characteristics for a new space, such as organizational profile (e.g., group characteristics of humans intended to occupy the new space), location, intended use, and/or a target occupancy for the new space. The computer system can select an occupancy distribution function derived from an existing space representing similar characteristics and apply this occupancy distribution function to the target occupancy to derive expected demand for different zone types across daily time windows. Based on this expected demand, the computer system can derive counts of zone types for the new space configured to support the target occupancy under expected operating conditions.

Furthermore, the computer system can apply the occupancy distribution function to derive how many humans can be assigned to the space. In particular, the computer system can compare a current or proposed total occupancy of the space to the practical capacity and derive whether assignment of additional humans would result in predicted unavailability of one or more zone types during expected time windows. Based on this determination, the computer system can indicate whether additional humans can be assigned to the space without exceeding the practical capacity.

In yet another example, the computer system can recalculate practical capacity of the space based on events associated with the space. For instance, in response to detecting an upcoming event assigned to a particular space and future time window, the computer system can incorporate an expected occupancy of the event into predicted distributions of humans throughout the space. The computer system can then recalculate practical capacity for the future time window corresponding to the event to account for event-driven demand on particular zone types.

Therefore, by deriving occupancy distribution functions from observed use of a space and applying these distributions to evaluate occupancy relative to zone type constraints over time, the computer system can calculate practical capacity for both existing and future sets of spaces to thereby enable occupancy, planning, refinement, and design of spaces, grounded human distribution throughout the space over time, rather than in static capacity assumptions or nominal limits.

### 2.4 Overcapacity Event Detection+Recommendations

Generally, Blocks of the method S100 can be executed by a computer system (e.g., a remote server): to collect detected human occupancy (herein “occupancy”) from sensor blocks arranged throughout spaces of a building (e.g., agile desks, conference rooms, lounges, and telephone booths within an office environment) within daily time windows; to derive a corpus of ratios between occupancies in these particular spaces and total occupancy of the building during these daily time windows; to calculate a current total occupancy of the building during a current time window; to calculate occupancy estimates of each space of the building during subsequent time windows based on the corpus of ratios and the current total occupancy; to detect an upcoming overcapacity event in the building based on an occupancy estimate for a particular space in the building for a particular subsequent time window on the current day that exceeds a particular occupancy capacity assigned to the particular space; and to generate an alert or prompt to preemptively address the upcoming overcapacity event.

For example, the computer system can detect an overcapacity event based on an occupancy estimate for conference rooms in an office building. The computer system can then preemptively address this overcapacity event by: generating a notification indicating that conference rooms in the building are only available for meetings with three or more humans during this particular time window; generating a recommendation for meetings with two humans to occur in another zone type (e.g., lounges); generating a recommendation to reschedule meetings in the conference room to a subsequent day; generating a recommendation to enforce reduced or strict time limits for meetings in conference rooms; or generating a recommendation to convert lounges into mini-conference rooms if lounges exhibit undercapacity events. The computer system can automatically prompt an administrator to distribute these recommendations to all employees prior to the overcapacity event or transmit these recommendations to all employees based on a set of rules or policies defined by the administrator.

Therefore, the computer system can: derive trends in relative distribution of humans across many spaces in the building during discrete time windows (e.g., 8 AM, 9 AM, 10 AM, 11 AM); derive trends correlating current total occupancy with total occupancy during future time windows; automatically predict a time and a location of an overcapacity event (or “an overutilization event,” “an excess demand event”) for spaces in the building based on these trends and the current total occupancy of the building; and automatically inform administrators, managers, employees, or other occupants of the building of such overcapacity events preemptively, thereby enabling these administrators, managers, employees, or other occupants to preemptively respond to these overcapacity events and avoid loss of productivity.

### 2.5 Occupancy Estimates+Overutilization

Additionally or alternatively, the computer system can implement Blocks of the method S100: to receive a new target total occupancy for the building from a user; and to identify a peak time window associated with a greatest total occupancy for the building. Based on the ratios of occupancy and the new target total occupancy for the building, the computer system can calculate occupancy estimates in each space of the building during this peak time window. Then, in response to an occupancy estimate for a particular space in the building during the peak time window exceeding a particular occupancy capacity assigned to the particular space, the computer system can: calculate a difference between the occupancy estimate and the particular occupancy capacity assigned to the particular space; and generate a recommendation to expand the particular space by the difference in order to support the new target total occupancy for the building. The computer system can repeat the methods and techniques described above to calculate estimated total occupancies in the building for each other time window and for each other space of the building to identify overutilization of any other space of the building.

Therefore, rather than interpreting total human occupancy count in the building based on square footage, the computer system can interpret total occupancy of the building—within particular daily time windows—based on how humans occupy and “use” spaces within the building. The computer system can then: identify particular spaces in the building that limit (or “bottleneck”) total human occupancy count of the building; estimate relationships between changes in actual total human occupancy count of the building and changes in sizes or total human occupancy count of particular spaces of the building (e.g., conference rooms, agile desks, telephone booths, lounges); and thus enable administrators, designers, or other managers of the building to assign types and distribution of spaces within the building to the target total occupancy of the building with precision adjustments to the building (e.g., adding conference rooms to the building, reducing agile desks in the building) based on actual historical utilization of the building by humans (e.g., a workforce) rather than generic industry data.

### 3. Sensor Block

A sensor block can include: a motion sensor defining a field of view and configured to detect motion in or near the field of view; a processor configured to interpret data from movement recorded by the motion sensor; a wireless communication module configured to wirelessly transmit these data; a battery or wired power supply configured to power the motion sensor, the processor, and the wireless communication module over an extended duration of time (e.g., one year, five years); and an housing configured to contain the motion sensor, the processor, the wireless communication module, and the battery. The housing is further configured to mount to a surface within the field of view of the motion sensor intersecting a doorway within the facility (e.g., a doorway to a board room, an entrance to a reception area) or a space within the building (e.g., a conference room or a desk area in an office building).

The motion sensor can include a passive infrared sensor (or “PIR” sensor) that defines a field of view and that passively outputs a signal representing movement of objects within (or near) the field of view of the motion sensor. The sensor block can: transition from an inactive state to an active state responsive to an output from the motion sensor indicating motion in the field of view of the motion sensor; trigger the motion sensor to record movement of an object; and interpret the movement as an entry/exit event into the space within the building.

In one variation, the sensor block includes an optical sensor defining a field of view. The optical sensor can include: a color camera configured to record and output two-dimensional color images; and/or a depth camera configured to record and output two-dimensional depth images or three-dimensional point clouds. However, the optical sensor can define any other type of optical sensor and can output visual or optical data in any other format.

In one example, the motion sensor is coupled to a wake interrupt pin on the processor. However, the motion sensor can define any other type of motion sensor and can be coupled to the processor in any other way to trigger the sensor block to enter a depth-capture mode, an area-capture mode, or an image-capture mode, responsive to motion in the field of view of the motion sensor.

In another variation, the sensor block also includes: a distance sensor (e.g., a 1D infrared depth sensor); an ambient light sensor; a temperature sensor; an air quality or air pollution sensor; and/or a humidity sensor. However, the sensor block can include any other ambient sensor. In the active state, the sensor block can sample and record data from these sensors and can selectively transmit these data-paired with insights extracted from movement or data recorded by the sensor block-to a local gateway. The sensor block can also include a solar cell or other energy harvester configured to recharge the battery.

The processor can locally execute Blocks of the method S100 to: selectively wake responsive to an output of the motion sensor; and trigger the depth sensor, area sensor, or optical sensor to record data, to write various insights extracted from the data, and to then queue the wireless communication module to broadcast these insights to a nearby gateway for distribution to the computer system.

The motion sensor, area sensor, depth sensor, optical sensor, battery, processor, wireless communication module, etc., can be arranged within a single housing configured to install on a flat surface—such as by adhering or mechanically fastening to a wall or ceiling—with the field of view of a corresponding sensor facing outwardly from the flat surface and intersecting a space within the building.

However, this “standalone,” “mobile” sensor block can define any other form and can mount to a surface in any other way.

### 3.1 Wired Power & Communications

In one variation, the sensor block additionally or alternatively includes a receptacle or plug configured to connect to an external power supply within the facility such as a power-over-Ethernet cable—and sources power for the sensors, processor, etc. from this external power supply. In this variation, the sensor block can additionally or alternatively transmit insights—extracted from motion events, depth data, area data, or images recorded by the sensor block—to the computer system via this wired connection (i.e., rather than wirelessly transmitting these data to a local gateway).

### 3.2 Depth Data+Area Data

In one implementation, each sensor block can: record a set of depth data in a field of view of a depth sensor arranged in the sensor block over a time interval (e.g., twenty-four hours); detect a set of humans in a corresponding space associated with the sensor block based on features detected in the set of depth data; generate a detected occupancy representing a quantity of humans present in the space at a daily time window (e.g., 8 AM, 9 AM, 10 AM, 11 AM, 12 PM, 1 PM) in the time interval; and transmit the detected occupancy to the computer system.

In another implementation, each sensor block can: record a set of area data in a field of view of an area sensor (e.g., a LIDAR sensor, a PIR sensor, an ultrasonic sensor, a radar sensor) arranged in the sensor block; detect a set of humans in a corresponding space associated with the sensor block based on features detected in the set of area data; generate a detected occupancy representing a quantity of humans present in the space during each daily time window; and transmit the detected occupancy to the computer system.

### 4. Setup Period: Map of Building

Generally, the computer system can access a map of the building (e.g., a floorplan) annotated with spaces or zone types of the building and/or occupancy capacities assigned to the building by a user (e.g., a resource manager, an administrator, an office manager). In particular, a user (e.g., an administrator) may: manually define spaces on the map of the building with bounding boxes via a user interface; and annotate each space with a quantity of humans assigned to the building.

In one implementation, an administrator may define spaces in a map of the building, annotate each space with a boundary, label the space with a maximum total human occupancy count (e.g., a maximum occupant limit, a maximum quantity of humans), and upload the annotated map via the user interface.

In one variation, during the setup period, the computer system: receives the annotated floorplan of the building from the user (e.g., an administrator) associated with the building via the user interface; prompts the user to highlight spaces or zone types on the floorplan via bounding boxes; receives an occupancy capacity (or “maximum human count”) for each space or zone type; and receives a set of identifiers—such as a list or a table of work titles or an employee badge number/code—associated with each human assigned to the space or zone type.

In one variation, the computer system can: access a set of sensor data (e.g., image data, depth data) from a population of sensor blocks distributed throughout a floor of a building; detect a set of spaces distributed throughout the floor-such as based on detection of agile desks, chair counts, detection of walls of a conference room, detection of telephone booths-based on the set of sensor data; and generate a map of the floor (e.g., a floorplan) based on the set of spaces distributed throughout the floor and locations of each zone type, in the set of zone types, in the target space within the floor.

In one implementation, the computer system can derive the floorplan of the target space based on sensor data (e.g., image data) captured by the population of sensor blocks deployed within the target space. For example, the computer system can access a first corpus of sensor data captured by a first population of sensor blocks, distributed throughout the target space, during a set of daily time windows; and derive a floorplan for the target space based on the first corpus of sensor data.

In one variation, the computer system can derive occupancy capacity for each zone type, in the set of zone types, for the target space based on a floorplan of the target space. For example, the computer system can: access a floorplan of the target space; detect a first quantity of desks in the floorplan; detect a second quantity of chairs in conference rooms in the floorplan; and detect a third quantity of phone booths in the floorplan. The computer system can then: generate a first occupancy capacity of a first zone type, in the set of zone types and including desks, based on the first quantity of desks; generate a second occupancy capacity of a second zone type, in the set of zone types and including conference rooms, based on the second quantity of chairs detected in conference rooms; and generate a third occupancy capacity of a third zone type, in the set of zone types and including phone booths, based on the third quantity of phone booths.

### 4.1 Sensor-Less Mapping

In one variation, the computer system can access and/or derive a map of the floor without sensor data and/or prior to sensor block deployment throughout the space.

For example, the computer system can: access a blueprint—such as uploaded by an administrator to an administrator portal—of the floor, the blueprint representing spatial constraints for the floor and/or intended types of spaces for the floor; and derive a set of characteristics for the floor based on the blueprint.

In another example, the computer system can: access a textual description of the floor—such as input by an administrator to an administrator portal—representing a design intention for the floor; extract a set of language signals from the textual description, the set of language signals defining the design intention for the floor; and derive a set of characteristics for the floor based on the set of language signals.

In yet another example, the computer system can: access a textual description of the floor—such as input by an administrator to an administrator portal—representing a count of spaces of each zone type (e.g., conference room, quiet workspace, open desk, etc.), in a set of zone types, and derive the set of characteristics of the floor based on the count of spaces of each zone type in the floor. In the foregoing example, the computer system can additionally or alternatively generate a virtual representation of the floor based on the set of characteristics.

Accordingly, the computer system can derive characteristics of a space (e.g., a set of spaces, a floor) based on a floorplan of the space and/or a textual description of the space prior to sensor block deployment within the space to preemptively derive practical capacity of the space and/or derive installation locations for sensor blocks within the space, as further described below.

### 4.2 Space Characteristics

Generally, the computer system can access and/or derive a set of characteristics of a space, such as a number of rooms in the space, a number of conference rooms in the space, a count and/or proportion of zone types (e.g., open focus space, enclosed focus space, open collaborative space, enclosed collaborative space), etc.

In one implementation, the computer system can derive characteristics of a space—or a target space—based on zone types detected in the floorplan of the target space. For example, the computer system can, for each space in the target space, derive a zone type, in a set of zone types, of the space based on a set of sensor data captured by a population of sensor blocks distributed throughout the target space; and derive a set of characteristics for the target space based on the set of zone types. In this example, the computer system can additionally: access a floorplan for a second target space; for each space in the second target space, derive a zone type, in a set of zone types, of the space; and derive the second set of characteristics based on the set of zone types.

For example, the computer system can access a first set of characteristics associated with the target space, the first set of characteristics representing counts of zone types represented within the target space. In this example, for a second target space distinct from the target space, the computer system can: access a second set of characteristics associated with the second target space, the second set of characteristics representing counts of spaces represented within the second target space; in response to the second set of characteristics approximating the first set of characteristics, predict a second distribution of humans throughout the second target space for a future time window based on the occupancy distribution function and/or a distribution of humans throughout the target space during a first time window corresponding to the future time window; generate a visualization representing the distribution of humans throughout the second target space for the future time window; and serve the visualization to an administrator via an administrator portal.

In one variation, the computer system can implement artificial intelligence and/or large language model methods to extract a set of characteristics of a space based on a textual description and/or image representation of the space.

Accordingly, the computer system can derive characteristics for a space representing visual characteristics of the space, such as zone types and/or a floorplan of the space.

### 4.3 Group Profiles

In another variation, the computer system can derive a set of characteristics for a space, the set of characteristics representing characteristics of humans occupying—or intended to occupy—the space.

In particular, the computer system can derive a set of characteristics for the space based on a textual description of a group of humans occupying the space—such as a group type (e.g., legal group, financial group, engineering group), a company type (e.g., a start-up, a large company), a count of employees in the company, etc.

In one example, the computer system can: access a first set of characteristics associated with the target space, the first set of characteristics representing characteristics of humans occupying the target space during the set of daily time windows; and associate an occupancy distribution function with the first set of characteristics. In this example, for a second target space (e.g., an empty floor) distinct from the target space, the computer system can: access a second set of characteristics associated with the second target space, the second set of characteristics representing characteristics of humans expected to occupy the second target space; in response to the second set of characteristics approximating the first set of characteristics, predict a second distribution of humans throughout the second target space for a second future time window based on the occupancy distribution function; generate a visualization representing the distribution of humans throughout the second target space for the second future time window; and serve the visualization to an administrator via an administrator portal.

In this implementation, the computer system can additionally or alternatively implement artificial intelligence and/or large language model methods to extract a set of characteristics of a space based on a textual description representation of the space.

In particular, the computer system can: access a textual description input by the administrator; extract a set of language signals, from the textual description, representing target characteristics of humans-intended to occupy a second target space—and corresponding to characteristics in a first set of characteristics for a target space; and derive a second set of characteristics, for the second target space, from the set of language signals.

### 5. Total Occupancy

Generally, the computer system can access and/or derive a total occupancy of the space.

In one implementation, the computer system can derive a total occupancy for a target space for each time window in a set of daily time windows based on a corpus of sensor data. In another implementation, the computer system can receive a total occupancy count—for a current time window—from an administrator via an administrator portal.

Additionally or alternatively, the computer system can predict future total occupancy for the space based on a total occupancy function, as further described herein.

### 5.1 Motion Events+Total Occupancy

Generally, each sensor block can track movement of objects, such as movement of humans in and out of an entrance or exit within a space of the building, over a period of time (e.g., one day) via the motion sensor. In particular, each sensor block can record entry/exit events for the particular space occurring during the time intervals within the period of time (e.g., one-hour time intervals) and transmit these entry/exit data to the computer system. The computer system can then derive a timeseries of entry/exit events for each time interval and thus, calculate a total occupancy for the space (e.g., a predicted quantity of humans occupying the space during the time interval).

Additionally or alternatively, each sensor block can derive a timeseries of entry/exit events and calculate a total occupancy for this space, rather than transmitting the entry/exit events to the computer system for calculation of the total occupancy for the space.

In one implementation, the sensor block: detects motion—within the field of view of the motion sensor arranged in the sensor block—representing movement of a human entering into or exiting from a doorway of a space in the building during a time interval assigned to this space; interprets movement of a human entering into the doorway of the space as an entry event; interprets movement of a human exiting from the doorway of the space as an exit event; records each occurrence of an entry event and exit event with a corresponding timestamp; and offloads these entry and exit events to the computer system for generation of a total occupancy representing a predicted quantity of humans occupying the space.

### 5.2 Depth Data+Occupancy

In one implementation, the sensor block detects motion within the field of view of the motion sensor arranged in the sensor block and, in response to detecting motion within the field of view of the motion sensor, captures a set of depth data—such as a depth map, a three-dimensional point cloud, reflectivity data, or depth values annotated with timestamps—at a depth sensor arranged in the sensor block. The sensor block then: detects a set of objects (e.g., humans) in a space of the building based on the set of depth data; generates a detected occupancy in the space based on the set of objects; and transmits the detected occupancy to the computer system. The computer system further receives these detected occupancies from each sensor block and generates a total occupancy representing a quantity of humans predicted to occupy a floor level, a particular space, and/or all spaces in the building.

In one variation, the sensor block: captures a depth map, in a set of depth maps, during a time window assigned to human counting via the depth sensor (e.g., between 8 AM and 9 AM, between 9 AM and 10 AM); detects a set of humans in a conference room located on a second floor of an office building based on the depth map; calculates a human count representing a quantity of humans present within the conference room during this time window based on the set of humans; and transmits the human count to the computer system. Accordingly, the computer system: generates a total occupancy representing a total quantity of humans predicted to occupy the second floor of the office building; and adjusts the total occupancy on the second floor based on the human count in the conference room.

In another variation, the computer system: accesses human counts from each sensor block deployed on each other floor of the office building; and selectively adjusts (e.g., increments or decrements) a total occupancy representing a quantity of humans predicted to occupy all spaces of the office building based on the human counts from each sensor block.

Therefore, each sensor block arranged in the building can capture depth data, detect objects present in the building, and generate a human count in the space intersecting a field of view of a depth sensor arranged in each sensor block. The computer system can then generate a detected occupancy in each space of the building and/or each floor of the building according to human count data from the population of sensor blocks. Thus, the computer system can generate an accurate occupancy in each space of the building rather than calculating a human count via motion data.

The method S100 is described herein as implementing motion and/or depth sensor data to calculate current total occupancy of a space. However, the computer system can implement any other method for calculating total occupancy of a space over time, such as: feature detection and extraction in images of the space captured by sensor blocks; entry and/or exit counts of humans entering and exiting the space (e.g., threshold sensors); counts of devices wirelessly connected to a wireless network associated with the space; etc.

### 5.3 Occupancy Count Prediction

In one implementation, the computer system can derive a total occupancy function configured to predict future occupancy of a target space- and in particular occupancy of each zone type in a set of zone types represented in the space-based on current occupancy of the target space in Block S122.

In particular, the computer system can: access a corpus of sensor data captured by a population of sensor blocks distributed throughout a space; derive a set of total occupancy counts of the space, throughout a set of daily time windows, based on the corpus of sensor data; and generate a total occupancy function based on the set of total occupancy counts of the space throughout the set of daily time windows, the total occupancy function configured to predict a future occupancy of the space for a particular time window, such as based on a current occupancy of the space.

Accordingly, the computer system can generate the total occupancy function based on the set of total occupancies and the set of daily time windows, the total occupancy function configured to map current occupancy counts to future occupancy counts of the target space.

In one implementation, the computer system can: access the corpus of sensor data captured by the population of sensor blocks, distributed throughout the set of spaces consisting of the target space, over a setup period preceding the first time period; based on the corpus of sensor data, generate a total occupancy function that predicts future total human occupancy counts in the target space during future time intervals based on current total human occupancy count in the target space during a current daily time interval; access a second corpus of sensor data captured by a set of sensor blocks, in the population of sensor blocks, during the second time period; derive an actual total human occupancy count within the target space during the second time period based on the second corpus of sensor data; and calculate the predicted total human occupancy count within the target space during the future time interval based on the total occupancy function and the actual occupancy within the target space during the second time period.

In one example, the computer system can, for each pair of daily time windows, in the set of daily time windows, including a first daily time window and a second daily time window occurring after the first daily time window: access a first total occupancy, in the set of total occupancies, associated with the first daily time window; access a second total occupancy, in the set of total occupancies, associated with the second daily time window; and calculate a change in total occupancy between the first total occupancy and the second total occupancy. In the foregoing example, the computer system can: categorize total occupancy changes based on a) a time offset between the first daily time window and the second daily time window and b) a time-of-day of the first daily time window; derive an expected change in total occupancy for each pair of daily time windows; and derive a total occupancy function (e.g., a function) that maps a current total occupancy associated with a current daily time window and a selected time offset to a predicted future total occupancy based on the expected change corresponding to the selected time offset and the time-of-day of the current daily time window.

In this implementation, the computer system can additionally or alternatively access a predicted future occupancy for a future time window for a particular space based on the total occupancy function. For example, the computer system can: access a total occupancy function configured to predict future occupancy of the target space; during the second time period, access a current occupancy for the target space; and generate a predicted future occupancy based on the current occupancy and the total occupancy function.

In a similar implementation, the computer system executes a total occupancy function to generate a timeseries of occupancy estimates representing predicted presence of humans in a particular zone type during the target time window.

In one variation, the computer system can receive input from a user via the user interface that defines a target daily time window, of interest to the user, for human occupancy simulation in a particular space of the building, on a floor of the building, or in the building. For example, the computer system can access detected occupancies, total occupancies, depth data, area data, or motion data captured by the population of sensor blocks during a similar time interval. The computer system can then execute the total occupancy function to predict occupancy estimates in each space of the building, such as a quantity of humans-per-hour likely to occupy each space of the building.

For example, the computer system can: receive a set of detected occupancies from a set of sensor blocks arranged in the building for a particular zone type at each time of day (e.g., 8 AM, 9 AM, 10 AM); track detected occupancies at each time of day over a period of time (e.g., one week, one month, two months); and access a total occupancy for the building representing a quantity of humans present within the building for each day within the time window (e.g., 160 humans present in the building on Monday, 200 humans present in the building on Tuesday). The computer system can then: retrieve a set of ratios (e.g., representative ratios) of occupancy associated with this zone type; input the detected occupancies, total occupancy, and the set of ratios of occupancy associated with the particular zone type into a total occupancy function; and execute the total occupancy function to generate an occupancy estimate representing predicted presence of humans in this zone type during the target time window.

In a similar variation, the computer system can predict a predicted total human occupancy count for the target space based on a time of day (e.g., daily time interval), a day of the week (e.g., Monday, Wednesday) specified by the daily time interval, weather characteristics (e.g., weather quality, sunny, cloudy, cold, rainy); and/or times of year (e.g., spring break, holidays, back-to-school date ranges).

In particular, the computer system can access the corpus of sensor data representing presence of humans in the set of spaces and labeled with: a time of day; a day of a week; and weather conditions intersecting the time of day. The computer system can then generate the total occupancy function that predicts future total occupancies based on: a time of day of future time intervals; a day of the week of future time intervals; and weather conditions intersecting future time intervals. The computer system can then: access a weather forecast intersecting with the future time interval; and calculate the predicted total human occupancy count based on a day of the week of the future time interval and the weather forecast for the future time interval.

Therefore, the computer system can execute a total occupancy function to predict an occupancy estimate in a target space during a target daily time window defined by a user in order to estimate a maximum total human occupancy count of the target space.

### 6. Occupancy Distribution Prediction

In the foregoing implementation, the computer system can implement machine learning and artificial intelligence techniques to develop occupancy distribution models that are configured to predict a likelihood of humans occupying each space of the building over daily time windows. In particular, the computer system can generate an occupancy distribution model for each space in the building that is configured to predict a likelihood of humans occupying each space of the building over a target daily time window selected by a user (e.g., a resource manager, an administrator, an office manager).

In one example, the computer system can: derive an occupancy distribution function based on a target space; associate the occupancy distribution function with a first set of characteristics of the target space; and select and/or implement the occupancy distribution function for a second target space that corresponds to (e.g., is similar to, us intended to be similar to) the target space, such as a second target space defining a second set of characteristics corresponding to the first set of characteristics.

In particular, the computer system can: access a first set of characteristics representing characteristics of humans occupying the target space during the set of daily time windows; associate the occupancy distribution function with the first set of characteristics; access a second set of characteristics representing characteristics of humans expected to occupy the second target space based on the text description; and, in response to the second set of characteristics approximating the first set of characteristics, derive a target practical capacity for the second target space based on the occupancy distribution function and the second set of characteristics.

Furthermore, a user may define a target daily time window (e.g., 10 AM, 11 AM, 12 PM, 1 PM) via a user interface, such as a native application executing on a computational device accessed by the user. The computer system can then receive the target daily time window from the user interface.

In one implementation, the computer system: tracks detected occupancies in spaces of the building over a period of time; detects a common occupancy in each space of the building across a set of daily time windows within a period of time (e.g., one day, one week); and derives total occupancy functions based on occupancy patterns (e.g., human behavior patterns) associated with these common occupancies. The computer system can then execute these total occupancy functions to generate a timeseries of occupancy estimates in each space of the building during the target time window and render visualizations of the timeseries of occupancy estimates within the user interface.

### 6.1 Occupancy Distribution: Per-zone Distribution

Generally, the computer system can: for each zone type, in a set of zone types, within the space, derive a zone-specific human occupancy count, in a set of zone-specific human occupancy counts, within the zone type within the space during the daily time interval; and derive an occupancy distribution function relating zone-specific human occupancy count for each zone type to total human occupancy count within the set of daily time intervals based on the set of total human occupancy counts and the set of zone-specific human occupancy counts.

In one implementation, the computer system: generates a zone-specific human occupancy count representing a count of humans present in a particular zone type within the space, such as based on a function of a total human occupancy count within the space during a corresponding daily time interval; and derives an occupancy distribution function based on historical zone-specific human occupancy counts and corresponding total human occupancy counts within the set of daily time intervals.

The computer system can repeat these methods and techniques for each zone type in the set of zone types and for each daily time interval in the set of daily time intervals to generate the occupancy distribution function relating zone-specific human occupancy counts to total human occupancy counts across the set of spaces.

In one implementation, the computer system can derive the occupancy distribution function configured to define, for each zone type and for each daily time interval, a mapping between total human occupancy within the space and a predicted zone-specific human occupancy count within the zone type, such that the occupancy distribution function can derive a maximum total human occupancy count predicted to yield a zone-specific human occupancy count equal to an occupancy capacity of the zone type.

For example, the computer system can: receive a corpus of detected occupancies from a set of sensor blocks arranged in all focus rooms of an office building and recorded on a particular day of the week (e.g., Monday); access the total occupancy representing a maximum quantity of humans present in the office building on this particular day; plot a first occupancy curve of humans present in a first focus room of the office building at each time of day based on a set of detected occupancies in the first focus room and the total occupancy; plot a second occupancy curve of humans present in a second focus room of the office building at each time of day based on a second set of detected occupancies in the second focus room and the total occupancy; and repeat these methods and techniques for each other focus room of the office building.

The computer system can then: calculate an average distribution of humans present in all focus rooms of the office building on this particular day based on a combination of these occupancy curves; and generate a function relating total occupancies within the office building across a set of daily time windows. The computer system can then automatically predict an occupancy estimate for all focus rooms in the office building during a subsequent time window (e.g., a time of day, a day of the week) according to the function.

Furthermore, the computer system can: calculate a set of occupancy ratios for each other space in the building; generate a function relating total occupancies within each other space in the building across a set of daily time windows; and automatically predict a total occupancy for each space in the building during a target time window (e.g., received via a user interface), as further described below.

In particular, the computer system can generate the predicted distribution of humans representing, for each daily time interval in the set of daily time intervals: a first representative ratio of a first representative human occupancy count within the first zone type, in the set of zone types, in a representative space to a representative total occupancy within the representative space; and a second representative ratio of a second representative human occupancy count within the second zone type, in the set of zone types, in the representative space to the representative total occupancy within the representative space. Then, based on the occupancy distribution function and the future time interval, the computer system can: calculate a first target ratio of a first human occupancy count within the first zone type in the target space to a first total occupancy within the target space; calculate a second target ratio of a second human occupancy count within the second zone type in the target space to the first total occupancy within the target space; calculate the first count of humans predicted to occupy the first zone type within the target space during the future time interval based on the first target ratio and the predicted total human occupancy count; and calculate a second count of humans predicted to occupy the second zone type within the target space during the future time interval based on the second target ratio and the predicted total human occupancy count.

Accordingly, the computer system can predict occupancy of each zone type, in the set of zone types, relative to a predicted total human occupancy count based on (pre-calculated) ratios-such as ratios defined by the occupancy distribution function-of humans occupying each zone type, in the set of zone types, relative to a predicted total human occupancy count.

### 7. Practical Capacity

Generally, the computer system can calculate a practical capacity of a target space, the practical capacity representing a target maximum capacity of the target space prior to failure of distribution of humans—such as based on capacity limits for each zone type in the set of zone types—based on a threshold failure proportion.

In one implementation, for a target space, the computer system can: access a first occupancy capacity of a first zone type within the target space; access a second occupancy capacity of a second zone type within the target space; based on the occupancy distribution function, calculate a first maximum total human occupancy count predicted to yield a first count of humans occupying the first zone type equal to the first occupancy capacity of the first zone type; and, based on the occupancy distribution function, calculate a second maximum total human occupancy count predicted to yield a second count of humans occupying the second zone type equal to the second occupancy capacity of the second zone type.

The computer system can then: compare the first maximum total human occupancy count and the second maximum total human occupancy count; and, in response to the first maximum total human occupancy count falling below the second maximum total human occupancy count, record the first maximum total human occupancy count as the practical capacity of the target space.

In one implementation, the computer system can: repeat these methods and techniques for each zone type in the set of zone types to calculate a set of maximum total human occupancy counts corresponding to occupancy capacities of the set of zone types; and select a lowest (e.g., minimum) maximum total human occupancy count in the set of maximum total human occupancy counts as the practical capacity of the target space, the zone type corresponding to the lowest maximum total human occupancy count defining a limiting zone type of the target space.

In one implementation, the computer system can: define the occupancy distribution function for each daily time interval in a set of daily time intervals; and calculate a first practical capacity of the target space for a first daily time interval and a second practical capacity of the target space for a second daily time interval, the second practical capacity different from the first practical capacity. In this implementation, the computer system can: detect a first zone type as the limiting zone type during the first daily time interval; and detect a second zone type as the limiting zone type during the second daily time interval.

In one example, the computer system can define the occupancy distribution function for each daily time interval in a set of daily time intervals, such as hourly intervals throughout a workday.

More specifically, for a first daily time interval corresponding to a morning work period, the computer system can calculate a first maximum total human occupancy count predicted to yield a first count of humans occupying a first zone type, such as desks, equal to a first occupancy capacity of the first zone type. In this implementation, the computer system can calculate occupancy of the first zone type proportionally increasing relative to the total human occupancy during the morning work period, such as in response to the first zone type defining a limiting zone type of the target space during the first daily time interval.

For a second daily time interval corresponding to a midday period, the computer system can calculate a second maximum total human occupancy count predicted to yield a second count of humans occupying a second zone type, such as conference rooms or phone booths, equal to a second occupancy capacity of the second zone type. In this implementation, the computer system can calculate (an increased) occupancy of the second zone type relative to total human occupancy during the midday period, such that the second zone type defines the limiting zone type of the target space during the second daily time interval.

Accordingly, the computer system can record a first practical capacity of the target space during the first daily time interval based on the first maximum total human occupancy count and record a second practical capacity of the target space during the second daily time interval based on the second maximum total human occupancy count, the first practical capacity different from the second practical capacity.

Therefore, the computer system calculates practical capacity separately for each daily time interval to reflect temporal variation in zone-specific human occupancy relative to occupancy capacities of the zone types. Thus, because practical capacity of the target space dynamically changes throughout the day in response to changing human work patterns, the computer system can calculate dynamic practical capacities across daily time intervals rather than remaining fixed based solely on aggregate seat count or static building design.

In another example, the computer system can: calculate a first practical capacity, representing maximum target occupancy of the target space, based on the occupancy distribution function and a maximum capacity of the target space in Block S150; access a target practical capacity for the target space in Block S152; and, in response to the first practical capacity deviating from the target practical capacity by greater than a threshold deviation, predict excess demand of a first space, of the first zone type and in the target space, based on the first practical capacity and the distribution of humans throughout the target space during the future time window in Block S154.

In another implementation, the computer system can calculate practical capacity for the space based on a predicted maximum total human occupancy count of the space during a peak time window. In particular, the computer system can: access a peak time window representing peak occupancy of a space; predict distribution of humans throughout the space during the time window such as based on an occupancy distribution function and/or a corpus of simulations of distributions of humans throughout the space, as further described below; and, in response to identifying successful distribution of humans throughout the space, calculate the practical capacity based on a predicted peak occupancy of the space.

For example, in this implementation, the computer system can: detect a peak time window associated with a greatest total occupancy within the first set of daily time windows and for a first space in Block S128; for a second space, select a target peak time window corresponding to the peak time window; derive a target practical capacity based on a predicted occupancy of the second space for the target peak time window; based on the occupancy distribution function and the target practical capacity, calculate an occupancy estimate of each space, in the second target space, during the peak time window; and derive the target practical capacity based on the occupancy estimate of each space, in the second target space, during the peak time window.

In another example, the computer system can generate the predicted distribution of humans including a second count of humans predicted to occupy a second zone type, in the set of zone types, within the target space during the future time interval; access a second occupancy capacity of the second zone type within the target space; and, in response to the first count of humans exceeding the first occupancy capacity of the first zone type within the target space and in response to the second count of humans falling below the second occupancy capacity of the second zone type within the target space, and based on the occupancy distribution function, calculate a maximum total human occupancy count, within the target space during the future time interval, predicted to yield a count of humans, occupying the first zone type within the target space during the future time interval, equal to the first occupancy capacity of the first zone type within the target space; and record the maximum total human occupancy count as a practical capacity of the target space during the future time interval.

In particular, in this variation, the computer system can access a corpus of sensor data captured by a population of sensor blocks, distributed throughout a set of spaces, during a first time period. The computer system can then, based on the corpus of sensor data, for each space in the set of spaces, and for each daily time interval in a set of daily time intervals: calculate a total human occupancy, in a set of total human occupancy counts, in the space during the daily time interval; and, for each zone type in a set of zone types within the space, derive a zone-specific human occupancy count, in a set of zone-specific human occupancy counts, within the zone type within the space during the daily time interval. Then, based on the corpus of sensor data, the computer system can derive an occupancy distribution function relating zone-specific human occupancy count for each zone type to total human occupancy count within the set of daily time intervals based on the set of total human occupancy counts and the set of zone-specific human occupancy counts.

Then, during a second time period succeeding the first time period, the computer system can: access a first occupancy capacity of a first zone type, in the set of zone types, within a target space; based on the occupancy distribution function, calculate a first maximum total human occupancy count, within the target space, predicted to yield a first count of humans, occupying the first zone type within the target space, equal to the first occupancy capacity of the first zone type within the target space during a first daily time interval in the set of daily time intervals; based on the occupancy distribution function, calculate a second maximum total human occupancy count, within the target space, predicted to yield a second count of humans, occupying the first zone type within the target space, equal to the first occupancy capacity of the first zone type within the target space during a second daily time interval, in the set of daily time intervals, succeeding the first daily time interval, the second maximum total human occupancy count different from the first maximum total human occupancy count; record the first maximum total human occupancy count as a first practical capacity of the target space during the first daily time interval; and record the second maximum total human occupancy count as a second practical capacity of the target space during the second daily time interval.

Accordingly, the computer system can identify practical capacities of a target space dependent on daily time intervals and movement patterns of humans throughout the target space.

Furthermore, the computer system can dynamically identify practical capacities of a target space dependent on daily time intervals and dependent on particular limiting zones of the target space throughout the daily time intervals. In particular, the computer system can: access a second occupancy capacity of a second zone type, in the set of zone types, within a target space; based on the occupancy distribution function, calculate a third maximum total human occupancy count, within the target space, predicted to yield a third count of humans, occupying the second zone type within the target space, equal to the second occupancy capacity of the second zone type within the target space during the first daily time interval; based on the occupancy distribution function, calculate a fourth maximum total human occupancy count, within the target space, predicted to yield a fourth count of humans, occupying the second zone type within the target space, equal to the second occupancy capacity of the second zone type within the target space during the second daily time interval, the fourth maximum total human occupancy count different from the third maximum total human occupancy count; in response to the first maximum total human occupancy count falling below the third maximum total human occupancy count, record the first maximum total human occupancy count as the first practical capacity of the target space during the first daily time interval; and, in response to the second maximum total human occupancy count falling below the fourth maximum total human occupancy count, record the second maximum total human occupancy count as the second practical capacity of the target space during the second daily time interval.

Therefore, the computer system can derive a practical capacity representing a maximum capacity a space can comfortably support, such that, when the space is at the practical capacity, each person occupying the space may occupy a zone type she desires to occupy within some threshold of failure (e.g., 3.5%). Furthermore, the computer system can derive a target practical capacity for a new space to enable an administrator to accurately design and/or arrange types of spaces within the new space to support the target practical capacity.

### 7.1 Occupancy+Capacity Simulation

Generally, the computer system can: generate a corpus of simulations representing simulations of distributions of humans throughout the space; calculate a proportion of successful distributions of humans based on the corpus of simulations; and, in response to the proportion of successful distributions of humans exceeding a threshold proportion (e.g., 97%), calculate a practical capacity of a target space based on the corpus of simulations.

In one implementation, the computer system can generate a corpus of simulations of distributions of humans throughout a target space to preemptively predict an overcapacity event.

For example, the computer system can: access an occupancy distribution function relating total occupancies within the target space across the set of daily time windows with ratios of occupancy in each space in the target space; generate a corpus of simulated distribution of humans throughout the target space based on the occupancy distribution function; calculate a proportion of simulated distribution of humans, in the corpus of simulated distribution of humans, representing overcapacity events; and predict an overcapacity event in response to the proportion of simulated distribution of humans exceeding a threshold proportion.

In one variation, the computer system can generate the corpus of simulations by simulating occupancy of the target space across the set of daily time windows, such that each simulation represents a distribution of humans throughout the target space (e.g., a count of humans occupying each zone type in the set of zone types) at a particular total occupancy and a particular time window relative to a predicted total occupancy of the target space. In particular, for each simulation in the corpus of simulations, the computer system can assign simulated humans to individual spaces according to the occupancy distribution function and can evaluate the simulation against space-type constraints of the target space to derive whether the simulation represents a successful distribution or an overcapacity event.

In this variation, the computer system can detect a simulation as successful in response to occupancy conditions that prevent humans from using the a target zone type, in the target space, occur no more than a tolerated proportion of the time and can calculate the practical capacity of the target space as a maximum total occupancy associated with a corpus of simulations exhibiting overcapacity events in no more than a threshold proportion of simulations (e.g., 3.5%).

For example, the computer system can: generate a set of simulations representing distributions of humans within the space during the future time interval based on the occupancy distribution function and the predicted total human occupancy count, each simulation in the set of simulations including a first count, in a first set of counts, of humans predicted to occupy the first zone type within the target space during the future time interval; and predict the overcapacity event within the target space during the future time interval in response to more than a threshold proportion of first counts, in the set of first counts, exceeding the first occupancy capacity of the first zone type within the target space. In particular, in the foregoing example, the computer system can predict the overcapacity event within the target space during the future time interval in response to more than a threshold proportion of first counts, in the set of first counts, exceeding the first occupancy capacity of the first zone type within the target space, the threshold proportion approximately equal to 3.5%.

In one example, the computer system can detect an overcapacity event based on exhaustion of a particular zone type rather than by aggregate occupancy of the target space. For instance, at a selected total occupancy value, the computer system can simulate a distribution of humans across zone types for a particular daily time window in which demand for enclosed meeting spaces is elevated relative to other zone types based on historical occupancy counts. In this simulation, assignment of simulated humans to enclosed meeting spaces can exceed an available capacity of the enclosed meeting spaces, even though available capacity remains in other zone types within the target space. Therefore, the computer system can classify the simulation as an overcapacity event based on unavailability of the enclosed meeting spaces, notwithstanding that the simulated total occupancy remains below a nominal capacity of the target space.

Therefore, the computer system can simulate distributions of humans throughout a target space to evaluate capacity of the target space based on variability and constraint interaction reflected in historical occupancy behavior, rather than based on static limits or single observed conditions, and to derive a practical capacity that accounts for how frequently occupancy conditions produce unusable states under normal operation.

### 7.2 Occupancy Capacity Selection

In one implementation, the computer system can dynamically define an occupancy capacity for each space based on external signals, such as the time of day, day of the week, detected occupancies representing a quantity of humans commonly present within each space, or any other signal accessible by the computer system.

In one variation, the computer system sets an occupancy capacity for a particular space based on a time of day of the target time window (e.g., defined by the user). For example, the computer system can define an occupancy capacity, such as 10 humans, for a conference room based on a time of day (e.g., 8 AM) defined by the user.

### 7.3 Practical Capacity of a New Space

In one implementation, the computer system can: access a representation of a new space; access a set of characteristics (e.g., characteristics of people occupying space, design intention, target maximum capacity) for the space; and derive a practical capacity for the space based on the occupancy distribution function. In particular, the computer system can derive a practical capacity for the new space-prior to occupation of the space and/or prior to deployment of sensor blocks within the space-based on expected distributions of people within the space throughout particular time windows (e.g., daily time windows, weekly time windows, monthly time windows, yearly time windows).

For example, the computer system can: access a spatial representation of a target space and/or access a text description (e.g., a design intention, a description of the spaces) associated with the target space; derive a set of characteristics for the target space based on the spatial representation and the text description; based on the occupancy distribution function and the set of characteristics, derive a target practical capacity for the target space, the target practical capacity representing a target maximum capacity of the target space prior to failure of distribution of humans; generate a visualization representing the target practical capacity for the target space; and serve the visualization to an administrator via an administrator portal.

In particular, the computer system can: generate a corpus of simulations representing distributions of a group of humans throughout the target space during a set of daily time windows based on the occupancy distribution function and the set of characteristics of the target space; for each simulation in the corpus of simulations, calculate a proportion of successful distribution of humans throughout the space; detect a set of simulations, in the corpus of simulations, representing proportions of successful distribution of humans throughout the space exceeding a threshold proportion; and calculate the practical capacity based on the set of simulations.

In the foregoing implementation, the computer system can serve a visualization representing a successful distribution of humans throughout the target space. In particular, the computer system can: pseudorandomly select a first simulation in the set of simulations; generate the visualization of the first simulation; and render the visualization for an administrator via an administrator portal.

Therefore, the computer system can predict practical capacity for a new space—prior to deployment of sensor blocks within the new space—to enable the administrator to design the new space to support the practical capacity. Furthermore, the computer system can predict practical capacity for a new space to automatically recommend design updates and/or new designs, as further described below.

### 8. Building Design: Refine Generally, the computer system can recommend design refinements for a target space based on a practical capacity and/or a target practical capacity for the target space.

In particular, the computer system can: calculate a difference between the maximum total human occupancy count and the predicted total human occupancy count within the target space during the future time interval; generate a recommendation to convert a portion of the second zone type into the first zone type within the target space in order to reduce the difference; and serve the recommendation to an administrator affiliated with the target space.

In one implementation, the computer system can: detect a difference between the practical capacity of the target space and a target practical capacity for the target space; interpret occupancy patterns and space utilization, of particular zone types, derived from historical occupancy of the target space; and recommend a modification (e.g., an addition, a conversion of one space to a second zone type) to the target space to address a zone type discrepancy associated with occupancy conditions occurring between the practical capacity and the target practical capacity.

In another implementation, the computer system can recommend addition of a particular zone type to the target space responsive to predicting an overcapacity event for a space of the particular zone type. In particular, the computer system can: calculate a first practical capacity, representing maximum target occupancy of the target space, based on the occupancy distribution function and a maximum capacity of the target space; access a target practical capacity for the target space; in response to the first practical capacity deviating from the target practical capacity by greater than a threshold deviation, predict excess demand of a first space, of the first zone type and in the target space, based on the first practical capacity and the distribution of humans throughout the target space during the future time window; and generate a recommendation to generate additional spaces of the first zone type in the target space.

Furthermore, in this implementation, the computer system can recommend transformation of a first zone type into a target zone type based on occupancy capacities and/or under-utilization of the first zone type.

For example, for a target space, the computer system can: calculate a first predicted occupancy count for a first zone type; calculate a second predicted occupancy count for a second zone type; in response to the first predicted occupancy count exceeding a first occupancy capacity for the first zone type and in response to the second predicted occupancy count falling below a second occupancy capacity for the second zone type, predict underutilization of a second space of the second zone type and in the target space in Block S142; calculate a first occupancy capacity for the first space in Block S156; and calculate a second occupancy capacity for the second space. The computer system can generate a recommendation to convert the second space, of the second zone type, into the first zone type to thereby accommodate the predicted occupancy for the target space during the target time period.

In one example, the computer system can: calculate a first predicted occupancy count for a first conference room; calculate a difference between the first predicted occupancy count for the first conference room and an occupancy capacity of the first conference room in Block S158; and generate a recommendation to expand the target space by a second conference room, supporting an occupancy corresponding to the difference, to support predicted demand of the target space for the future time window.

In a similar implementation, in response to a target practical capacity differing from a calculated practical capacity, the computer system can: select a first zone type representing limited demand (e.g., underutilization); select a second zone type representing excess demand (e.g., overutilization); and recommend transformation of a first space, of the first zone type, into a second space of the second zone type.

For example, in response to a target maximum capacity deviating from the target practical capacity by greater than a threshold difference, the computer system can: in response to the target maximum capacity exceeding the target practical capacity, calculate a difference between the target maximum capacity and the target practical capacity; based on the occupancy distribution function, predict underutilization of a first space, in the second target space and of a first zone type, and overcapacity of a second space in the second target space and of a second zone type; in response to an occupancy capacity of the first zone type corresponding to the difference between the target maximum capacity and the target practical capacity, generate a recommendation to transform the first space into the second zone type; and serve the recommendation to an administrator via an administrator portal.

More specifically, the computer system can: receive a target total occupancy for the target space from the administrator via the administrator portal; and, in response to the target total occupancy exceeding the target practical capacity, generate a corpus of simulations representing distributions of humans throughout the target space based on the occupancy distribution function, the target total occupancy, and the spatial representation. Then, for a first simulation in the corpus of simulations, the computer system can: predict a first overcapacity event based on a first distribution of humans throughout the target space; detect a first space, of a first zone type and in the target space, associated with the first overcapacity event; calculate a first count of humans associated with the first overcapacity event; and generate a recommendation to generate a space, of the first zone type and with an occupancy capacity corresponding to the first count of humans, in the target space. The computer system can then serve the recommendation to the administrator portal, such as responsive to an administrator prompt input at the administrator portal.

Additionally or alternatively, the computer system can implement methods and techniques as described herein for a peak time window to derive the target total occupancy of a space. In particular, the computer system can: calculate an occupancy estimate of each zone type, in the set of zone types, in the target space, during a peak time window-representing a time window of maximum total human occupancy count of the target space-based on the occupancy distribution function and the target practical capacity; access a target total occupancy for the target space; in response to the target total occupancy exceeding the target practical capacity and in response to a first occupancy estimate for a first space, in the target space, exceeding a first occupancy capacity assigned to the first space, calculate a difference between the first occupancy estimate and the first occupancy capacity; and generate a recommendation to expand the first space by the difference to support the target total occupancy for the target space.

In another implementation, the computer system can: recommend updates (e.g., temporary updates, permanent updates) to the target space based on predicted future occupancy for the target space; and iteratively modify representations (e.g., virtual representations, floorplans) of the target space based on these recommended updates.

For example, the computer system can: access a predicted future occupancy of the second target space for a future time window; generate a corpus of simulations representing distributions of humans throughout the second target space during the future time window based on the occupancy distribution function and the target practical capacity; and, for each simulation in the corpus of simulations, calculate a proportion of successful distribution of humans throughout the second target space. In response to the proportion of successful distribution of humans throughout the second target space falling below a threshold proportion, the computer system can: detect a first space, in the second target space, as capacity-limiting in the target space during the future time interval in Block S144; generate a modified spatial representation, based on expansion of the first space, to satisfy the target practical capacity in Block S182; and serve the modified spatial representation to the administrator portal.

More specifically, in this example, the computer system can select a set of simulations, in the corpus of simulations, representing unsuccessful distribution of humans throughout the second target space and, for each for each simulation in the set of simulations: detect a first space associated with unsuccessful distribution of humans throughout the second target space; access an occupancy capacity of the first zone type; and detect the first space as the source of overcapacity in response to a predicted occupancy for the first space according to the simulation exceeding the occupancy capacity of the first zone type. The computer system can then: calculate a difference between the occupancy capacity of the first zone type and the predicted occupancy for the first space in Block S146; and expand a representation of the first space in the spatial representation by the difference in Block S160.

Additionally or alternatively, during a third time period, the computer system can: access a predicted future occupancy of the second target space for a future time window; generate a corpus of simulations representing distributions of humans throughout the second target space during the future time window based on the occupancy distribution function and the target practical capacity; for each simulation in the corpus of simulations, calculate a proportion of successful distribution of humans throughout the second target space; in response to the proportion of successful distribution of humans throughout the second target space falling below a threshold proportion, detect a first space, in the second target space, as capacity-limiting in the target space during the future time interval based on the predicted future occupancy; generate a modified spatial representation based on expansion of the first space; and serve the modified spatial representation to the administrator portal.

Therefore, the computer system can automatically recommend refinements for design of the target space—such as zone types, space counts, and/or occupancy capacities—based on iterative simulation of future distributions of humans throughout the space.

Generally, the computer system can automatically generate a use of building recommendation for a space of the building and/or the building in order to improve utilization and occupancy in a space of the building and/or within the building. Thus, the computer system can recommend specific steps to a user (e.g., a resource manager, an administrator, an office manager) of the building based on occupancy rates, capacity failures, and the maximum capacity of the building.

In particular, responsive to an occupancy estimate for a particular space in a current time window within the building exceeding a particular occupancy capacity assigned to the particular space, the computer system can generate an alert to preemptively address excess demand of a particular space in a subsequent time window.

In one implementation, the computer system can receive a set of space priorities for the building from a user via the user interface. The computer system can then automatically detect when a space and/or an entire zone type—corresponding to a highest space priority—exhibits an overcapacity event during the target window previously selected by the user. The computer system can then generate specific recommendations associated with the space or the entire zone type to the user in response to detecting the overcapacity event.

In one example, the computer system can, in response to a space exhibiting an overcapacity event, generate a recommendation to assign extra workers (e.g., a quantity of humans exceeding the occupancy capacity) to a next highest space priority. In another example, the computer system can, in response to a space exhibiting an overcapacity event, generate a recommendation to assign a quantity of workers to the space less than the occupancy capacity associated with this space. In yet another example, the computer system can, in response to a zone type exhibiting an overcapacity event over a simulated period of time (e.g., a week, a month), generate a recommendation to assign extra workers to another building (e.g., an office building).

### 8.1 Variation: Building Design

In another variation, the computer system can generate a recommended target space for a building (e.g., a floor of a building, a space within a building) based on predicted distribution of humans intended to occupy the building.

In particular, the computer system can: implement methods and techniques as described herein for a target space, representing a first set of characteristics, to derive an occupancy distribution function mapping ratios of occupancy to zone types, in the target space, based on daily time windows; access a text description of a design intention for a second target space; extract a first set of language signals from the text description; derive a second set of characteristics for the second target space based on the first set of language signals; derive a target practical capacity for the second target space based on the second set of characteristics; based on the occupancy distribution function and the target practical capacity, derive a spatial representation (e.g., a floorplan, a recommended count of zone types) for the second target space; and serve the spatial representation to an administrator via an administrator portal.

In one example, the computer system can derive a predicted count of particular zone types for the target space, such as counts of open collaboration spaces, closed collaboration spaces, open focus spaces, and closed focus spaces. In particular, the computer system can: for each zone type in a count of zone types, derive a count of spaces, of the zone type, for the second target space based on the occupancy distribution function; access a set of dimensions for the second target space; initialize a visualization representing the set of dimensions; and arrange the count of spaces of each zone type within the visualization.

In one example, the computer system can: access a first count of conference rooms in the target space; access a second count of agile desks in the target space; access characteristics of a first group of humans occupying the target space; derive characteristics of a second group of humans expected to occupy a second target space; and, in response to characteristics of the first group of humans corresponding to characteristics of the second group of humans, deriving a spatial representation for the second target space including a third count of conference rooms approximating the first count of conference rooms in the target space and a fourth count of agile desks approximating the second count of agile desks in the target space.

In one implementation, the computer system can generate a representation of the second target space based on simulating a corpus (e.g., 1000 s) of distributions of humans throughout the space during a set of daily time windows and selecting a successful distribution of humans throughout the space during a peak time window.

In particular, in this implementation, the computer system can: generate a corpus of simulations representing distributions of the group of humans intended to occupy the second target space throughout a second set of daily time windows based on the occupancy distribution function and the target practical capacity; for each simulation in the corpus of simulations, calculate a proportion of successful distribution of humans throughout the space; detect a set of simulations, in the corpus of simulations, representing proportions of successful distribution of humans throughout the space exceeding a threshold proportion; pseudorandomly select a first simulation in the set of simulations; generate a visualization representation of the first simulation; and render the visualization to an administrator via an administrator portal.

### 8.1.1 Sensor Block Installation Location

In one implementation, the computer system can predict locations for installation of sensor blocks for the new target space based on distributions of sensor blocks throughout a historical set of spaces and counts of humans detected by these sensor blocks.

For example, for each sensor block in a first population of sensor blocks distributed throughout a target space, the computer system can: derive a count of humans detected by the sensor block during the set of daily time windows in Block S190; associate the count of humans with the sensor block in Block S192; select a set of sensor blocks in the population of sensor blocks based on counts of humans, associated with sensor blocks in the set of sensor blocks, exceeding a threshold count of humans in Block S194; and access a set of installation locations for the set of sensor blocks in Block S195. The computer system can then assign the set of installation locations to a second target space approximating the target space. For example, the computer system can derive a spatial representation for the second target space, the spatial representation including a second set of installation locations for a second population of sensor blocks for the second target space based on the set of installation locations for the set of sensor blocks.

In this implementation, the computer system can iteratively identify sensor blocks for removal and/or addition to the new target space once these sensor blocks have been deployed within the new target space, such as responsive to counts of humans detected by these sensor blocks during a second set of daily time windows.

In particular, for each sensor block in the second population of sensor blocks, the computer system can: derive a count of humans detected by the sensor block during a second set of daily time windows in Block S190; in response to the count of humans falling below a threshold count of humans, detect overlap between a first field of view of the sensor block and a second field of view of a second sensor block in the second population of sensor blocks in Block S196; and recommend removal of the sensor block in Block S198.

Therefore, in the foregoing implementations, the computer system can predict and/or recommend target installation locations for sensor blocks for a new target space, and/or iteratively recommend addition or removal of sensor blocks, based on productivity of these sensor blocks to reduce a power load of these sensor blocks and to reduce personal information collected by these sensor blocks over time.

### 8.2 Visualizations

Generally, the computer system can generate and render a visualization representing predicted occupancy of the target space to an administrator portal. In particular, the computer system can: generate a corpus of simulations of occupancy of a target space; pseudorandomly select a simulation in the corpus of simulations; generate a visualization representing the simulation, such as a visualization of a distribution of humans throughout the target space predicted by the simulation; and render the visualization for an administrator in an administrator portal.

In one example, the computer system can: select a sample simulation from a set of simulations; and populate a graphical representation of the target space during the future time interval with a first count, in the set of first counts, of humans predicted to occupy the first zone type within the target space during the future time interval according to the sample simulation, and a second count of humans predicted to occupy a second zone type, in the set of zone types, within the target space during the future time interval according to the sample simulation. The computer system can then render the graphical representation on a display accessed by a user affiliated with the target space.

In one implementation, the computer system can render an occupancy estimate relative to a corresponding occupancy capacity of each space within the user interface. In particular, the computer system can: render a two-dimensional line plot depicting changes in occupancy estimates over a set of daily time windows on a current day; render a two-dimensional histogram depicting occupancy estimates during each daily time window on the current day relative to corresponding occupancy capacities; and/or render a heatmap depicting occupancy patterns across the set of daily time windows.

For example, the computer system populates a visualization, such as a two-dimensional line plot, with representations of the occupancy estimates in each space relative to the occupancy capacity defined for each space. In particular, the computer system can: generate a two-dimensional line graph for a particular space; populate the two-dimensional line graph with a horizonal line (e.g., a fixed line) corresponding to an occupancy capacity associated with this particular space; populate the two-dimensional line graph with time-of-day values corresponding to each occupancy value from a set of occupancy estimates in this particular space along a first axis (e.g., an x-axis); and populate the two-dimensional line graph with occupancy values from the set of occupancy estimates in this particular space along a second axis (e.g., a y-axis). The computer system further generates a two-dimensional line graph for each space in the building and populates these line graphs with corresponding values from the set of occupancy estimates generated for each space over the target daily time window. The computer system then renders these two-dimensional line graphs in the user interface.

Therefore, the computer system can render a set of visualizations within the user interface, thereby enabling a user to review occupancy estimates in spaces of the building across daily time windows (e.g., peak work hours, a particular day of the week, a particular week).

### 9. Overcapacity Events+Maximum Building Capacity

In one implementation, the computer system can predict capacity failures in spaces of the building during the time window of interest to a user and increment and decrement a capacity counter representing a maximum capacity for the building at a time of a predicted capacity failure. The computer system can then increment and decrement a capacity counter proportional to the occupancy estimate values depicted in the visualizations. Responsive to an intersection between a particular occupancy estimate in a particular space and a corresponding occupancy capacity associated with the particular space, the computer system can: predict a capacity failure at the time of day corresponding to the intersection; and access a maximum capacity of humans for the building from the capacity counter.

In one variation, responsive to an occupancy estimate value in a particular space exceeding a corresponding occupancy capacity associated with the particular space, the computer system can: identify the intersection as an overcapacity event (e.g., a shortage of the space); flag a representation (e.g., highlight or annotate with a dot or a marker) corresponding to the occupancy estimate value within a corresponding visualization; and generate an alert to preemptively address excess demand of the particular space.

Generally, the computer system can preemptively notify an administrator of the predicted overcapacity event prior to the target time window.

In particular, the computer system can: access (and/or predict) a future occupancy of a target space for a future time window; based on the occupancy distribution function, predict a distribution of humans throughout the target space; based on the future occupancy of the target space, calculate a predicted count of humans occupying each zone in the target space; detect a first space predicted to be occupied by a count of humans exceeding an occupancy capacity of the first zone type; and predict an overcapacity event during the future time window.

Furthermore, the computer system can: derive a difference between a first predicted occupancy count and a count of available seats of a first zone type in the target space; generate a prompt including the future time window and the difference between the first predicted occupancy count and the count of available seats of the first zone type in the target space; and serve the prompt to a mobile computing device associated with an administrator, prior to the future time window, to preemptively address excess demand of the first zone type in the future time window.

Therefore, the computer system can preemptively notify an administrator of the predicted overcapacity event prior to occurrence of the overcapacity event to enable the administrator to preemptively mitigate distribution of these humans during the future time window. Additionally, the computer system can predict a capacity failure in spaces of the building and indicate these capacity failures within visualizations in the administrator portal. The computer system can further render these visualizations and the maximum capacity of the building within the user interface, and thereby enable a user to accurately plan policies (e.g., return-to-work policies, after-hours policies) and assign teams to a space, a floor, or to the building without exceeding the maximum capacity of the building.

### 9.1 Variation: Event-based Overcapacity+Recommendations

In one variation, the computer system can implement methods and techniques as described herein based on particular events (e.g., board meetings, client on-site meetings, large gatherings) assigned to the target space. In particular, the computer system can: access an event on a calendar for the target space; (e.g., responsive to administrator input); extract a time window, a zone type (e.g., a particular conference room) assigned to the event, and an expected occupancy count for the event; and predict a distribution of humans throughout the target space, for the time window, based on assignment of the expected occupancy count to the space. The computer system can then: predict an overcapacity event in a second zone type in the target space; and preemptively reassign humans, associated with the overcapacity event of the second space, to a third space (e.g., work from home, work from a second zone type within the target space).

For example, the computer system can: access a calendar representing events occurring in spaces in the target space in Block S170; detect an event of interest represented in the calendar, the event of interest designating a first count of humans and occupation of a first space, in the target space, during the future time window in Block S172; access a future time window associated with the event of interest in Block S174; predict a distribution of humans throughout the target space based on occupation of the first space by the first count of humans; and predict overcapacity of a second space, in the target space, based on the distribution of humans throughout the target space designating a second count of humans occupying the second space, the second count of humans exceeding an occupancy capacity for the second space.

The computer system can then: select a subset of humans, in the second count of humans in Block S175; generate a recommendation to reassign the subset of humans to a third space, distinct from the second space, for the future time window in Block S176; and serve the recommendation to a mobile computing device associated with an administrator, prior to the future time window, to preemptively address excess demand of the second space in the future time window.

Therefore, by incorporating event-based occupancy into prediction of future distributions of humans throughout the target space, the computer system can identify and mitigate overcapacity events prior to a future time window, rather than responsive to observed congestion, to thereby recommend adjustments to use of the target space, which may be executed in advance of the events that drive excess demand, reducing reliance on reactive reassignment following overcapacity events.

The systems and methods described herein can be embodied and/or implemented at least in part as a machine configured to receive a computer-readable medium storing computer-readable instructions. The instructions can be executed by computer-executable components integrated with the application, applet, host, server, network, website, communication service, communication interface, hardware/firmware/software elements of a user computer or mobile device, wristband, smartphone, or any suitable combination thereof. Other systems and methods of the embodiment can be embodied and/or implemented at least in part as a machine configured to receive a computer-readable medium storing computer-readable instructions. The instructions can be executed by computer-executable components integrated by computer-executable components integrated with apparatuses and networks of the type described above. The computer-readable medium can be stored on any suitable computer readable media such as RAMs, ROMs, flash memory, EEPROMs, optical devices (CD or DVD), hard drives, floppy drives, or any suitable device. The computer-executable component can be a processor but any suitable dedicated hardware device can (alternatively or additionally) execute the instructions.

As a person skilled in the art will recognize from the previous detailed description and from the figures and claims, modifications and changes can be made to the embodiments of the invention without departing from the scope of this invention as defined in the following claims.

I claim:

1. A method comprising:
accessing a corpus of sensor data captured by a population of sensor blocks, distributed throughout a set of spaces, during a first time period;
based on the corpus of sensor data:
for each space in the set of spaces:
for each daily time interval in a set of daily time intervals:
calculating a total human occupancy count, in a set of total human occupancy counts, in the space during the daily time interval; and
for each zone type, in a set of zone types, within the space, deriving a zone-specific human occupancy count, in a set of zone-specific human occupancy counts, within the zone type within the space during the daily time interval; and
deriving an occupancy distribution function relating zone-specific human occupancy count for each zone type to total human occupancy count within the set of daily time intervals based on the set of total human occupancy counts and the set of zone-specific human occupancy counts; and
during a second time period succeeding the first time period:
accessing a predicted total human occupancy count within a target space during a future daily time interval;
based on the occupancy distribution function, the predicted total human occupancy count, and the future time interval:
generating a predicted distribution of humans occupying the set of zone types within the target space during the future daily time interval, the predicted distribution of humans comprising a first count of humans predicted to occupy a first zone type, in the set of zone types, within the target space during the future time interval;
accessing a first occupancy capacity of the first zone type within the target space; and
in response to the first count of humans exceeding the first occupancy capacity of the first zone type within the target space:
predicting an overcapacity event within the target space during the future daily time interval.

2. The method of claim 1:
wherein accessing the corpus of sensor data captured by the population of sensor blocks comprises accessing the corpus of sensor data captured by the population of sensor blocks, distributed throughout the set of spaces consisting of the target space, over a setup period preceding the first time period;
further comprising, based on the corpus of sensor data, generating a total occupancy function that predicts future total human occupancy counts in the target space during future time intervals based on current total human occupancy count in the target space during a current daily time interval; and
wherein accessing the predicted total human occupancy count within the target space during the future time interval comprises:
accessing a second corpus of sensor data captured by a set of sensor blocks, in the population of sensor blocks, during the second time period;
deriving an actual total human occupancy count within the target space during the second time period based on the second corpus of sensor data; and
calculating the predicted total human occupancy count within the target space during the future time interval based on:
the total occupancy function; and
the actual occupancy within the target space during the second time period.

3. The method of claim 2:
wherein accessing the corpus of sensor data comprises accessing the corpus of sensor data representing presence of humans in the set of spaces and labeled with:
a time of day;
a day of a week; and
weather conditions intersecting the time of day;
wherein generating the total occupancy function that predicts future total occupancies in the target space during future time intervals comprises:
generating the total occupancy function that predicts future total occupancies based on:
a time of day of future time intervals;
a day of the week of future time intervals; and
weather conditions intersecting future time intervals; and
wherein calculating the predicted total human occupancy count comprises:
accessing a weather forecast intersecting with the future time interval; and
calculating the predicted total human occupancy count further based on:
a day of the week of the future time interval; and
the weather forecast for the future time interval.

4. The method of claim 1:
wherein accessing the corpus of sensor data captured by the population of sensor blocks comprises accessing the corpus of sensor data captured by the population of sensor blocks, distributed throughout the set of spaces excluding the target space, over a setup period preceding the first time period; and
wherein accessing the predicted total human occupancy count within the target space during the future time interval comprises accessing the predicted total human occupancy count within the target space manually entered by a user via a user interface rendered on a computing device.

5. The method of claim 1:
wherein generating the predicted distribution of humans occupying the set of zone types within the target space during the future time interval comprises generating the predicted distribution of humans further comprising a second count of humans predicted to occupy a second zone type, in the set of zone types, within the target space during the future time interval; and
further comprising:
accessing a second occupancy capacity of the second zone type within the target space; and
in response to the first count of humans exceeding the first occupancy capacity of the first zone type within the target space and in response to the second count of humans falling below the second occupancy capacity of the second zone type within the target space, identifying the first zone type as capacity-limiting in the target space during the future time interval.

6. The method of claim 1:
wherein generating the predicted distribution of humans occupying the set of zone types within the target space during the future time interval comprises generating the predicted distribution of humans further comprising a second count of humans predicted to occupy a second zone type, in the set of zone types, within the target space during the future time interval; and
further comprising:
accessing a second occupancy capacity of the second zone type within the target space; and
in response to the first count of humans exceeding the first occupancy capacity of the first zone type within the target space and in response to the second count of humans falling below the second occupancy capacity of the second zone type within the target space:
based on the occupancy distribution function:
calculating a maximum total human occupancy count, within the target space during the future time interval, predicted to yield a count of humans, occupying the first zone type within the target space during the future time interval, equal to the first occupancy capacity of the first zone type within the target space; and
recording the maximum total human occupancy count as a practical capacity of the target space during the future time interval.

7. The method of claim 6, further comprising:
calculating a difference between the maximum total human occupancy count and the predicted total human occupancy count within the target space during the future time interval;
generating a recommendation to convert a portion of the second zone type into the first zone type within the target space in order to reduce the difference; and
serving the recommendation to an administrator affiliated with the target space.

8. The method of claim 6, further comprising:
calculating a difference between the maximum total human occupancy count and the predicted total human occupancy count within the target space during the future time interval;
generating a recommendation to reduce headcount within the target space prior to the future time interval by the difference; and
serving the recommendation to an administrator affiliated with the target space.

9. The method of claim 1:
further comprising:
accessing a calendar associated with the target space; and
detecting an event of interest, occurring in the target space and specifying the future time interval, in the calendar; and
wherein generating the predicted distribution of humans occupying the set of zone types within the target space during the future time interval comprises:
generating the predicted distribution of humans occupying the set of zone types within the target space during the future time interval in response to detecting the event of interest in the calendar.

10. The method of claim 1:
further comprising accessing a set of target characteristics of the target space;
wherein accessing the corpus of sensor data comprises accessing the corpus of sensor data captured by the population of sensor blocks distributed throughout the set of spaces exhibiting characteristics approximating the set of target characteristics; and
wherein deriving the occupancy distribution function comprises deriving the occupancy distribution function relating zone-specific human occupancy counts for each zone type to total human occupancy counts within spaces analogous to the target space.

11. The method of claim 1:
wherein accessing the corpus of sensor data comprises the corpus of sensor data captured by the population of sensor blocks distributed throughout the set of spaces, each space in the set of spaces comprising a floor of an office; and
wherein deriving a zone-specific human occupancy count within a zone type within a space during a daily time interval comprises, based on the corpus of sensor data and for each space in the set of spaces:
for each daily time interval, comprising a one-hour period, in the set of daily time intervals and for each zone type, in the set of zone types comprising agile desks, conference rooms, and phone booths, within the space:
deriving a zone-specific human occupancy count within the zone type within the space during the daily time interval.

12. The method of claim 1:
further comprising:
accessing a floorplan of the target space;
detecting a first quantity of desks in the floorplan;
detecting a second quantity of chairs in conference rooms in the floorplan; and
detecting a third quantity of phone booths in the floorplan; and
wherein accessing the first occupancy capacity of the first zone type within the target space comprises:
generating the first occupancy capacity of the first zone type, in the set of zone types and comprising desks, based on the first quantity of desks;
generating a second occupancy capacity of the second zone type, in the set of zone types and comprising conference rooms, based on the second quantity of chairs detected in conference rooms; and
generating a third occupancy capacity of the third zone type, in the set of zone types and comprising phone booths, based on the third quantity of phone booths.

13. The method of claim 1:
wherein generating the predicted distribution of humans occupying the set of zone types within the target space during the future time interval comprises:
generating the predicted distribution of humans further representing, for each daily time interval in the set of daily time intervals:
a first representative ratio of a first representative human occupancy count within the first zone type, in the set of zone types, in a representative space to a representative total occupancy within the representative space; and
a second representative ratio of a second representative human occupancy count within the second zone type, in the set of zone types, in the representative space to the representative total occupancy within the representative space; and
based on the occupancy distribution function and the future time interval:
calculating a first target ratio of a first human occupancy count within the first zone type in the target space to a first total occupancy within the target space;
calculating a second target ratio of a second human occupancy count within the second zone type in the target space to the first total occupancy within the target space;
calculating the first count of humans predicted to occupy the first zone type within the target space during the future time interval based on the first target ratio and the predicted total human occupancy count; and
calculating a second count of humans predicted to occupy the second zone type within the target space during the future time interval based on the second target ratio and the predicted total human occupancy count.

14. The method of claim 1:
wherein generating the predicted distribution of humans occupying the set of zone types within the target space during the future time interval comprises:
generating a set of simulations representing distributions of humans within the space during the future time interval based on the occupancy distribution function and the predicted total human occupancy count, each simulation in the set of simulations comprising a first count, in a first set of counts, of humans predicted to occupy the first zone type within the target space during the future time interval; and
wherein predicting the overcapacity event within the target space during the future time interval comprises predicting the overcapacity event within the target space during the future time interval in response to:
more than a threshold proportion of first counts, in the set of first counts, exceeding the first occupancy capacity of the first zone type within the target space.

15. The method of claim 14:
wherein predicting the overcapacity event within the target space during the future time interval comprises predicting the overcapacity event within the target space during the future time interval in response to:
more than a threshold proportion of first counts, in the set of first counts, exceeding the first occupancy capacity of the first zone type within the target space, the threshold proportion approximately equal to 3.5%.

16. The method of claim 14:
further comprising:
selecting a sample simulation from the set of simulations;
populating a graphical representation of the target space during the future time interval with:
a first count, in the set of first counts, of humans predicted to occupy the first zone type within the target space during the future time interval according to the sample simulation; and
a second count of humans predicted to occupy a second zone type, in the set of zone types, within the target space during the future time interval according to the sample simulation; and
rendering the graphical representation on a display accessed by a user affiliated with the target space.

17. A method comprising:
accessing a corpus of sensor data captured by a population of sensor blocks, distributed throughout a space, during a first time period;
based on the corpus of sensor data:
for each daily time interval in a set of daily time intervals:
calculating a total human occupancy, in a set of total human occupancy counts, in the space during the daily time interval; and
for each zone type, in a set of zone types, within the space, deriving a zone-specific human occupancy count, in a set of zone-specific human occupancy counts, within the zone type within the space during the daily time interval; and
deriving an occupancy distribution function relating zone-specific human occupancy count for each zone type to total human occupancy count within the set of daily time intervals based on the set of total human occupancy counts and the set of zone-specific human occupancy counts; and
during a second time period succeeding the first time period:
accessing a predicted total human occupancy count within the space during a future time interval;
based on the occupancy distribution function, the predicted total human occupancy count, and the future time interval:
generating a predicted distribution of humans occupying the set of zone types within the space during the future time interval, the predicted distribution of humans comprising a first count of humans predicted to occupy a first zone type, in the set of zone types, within the space during the future time interval;
accessing a first occupancy capacity of the first zone type within the space; and
in response to the first count of humans exceeding the first occupancy capacity of the first zone type within the space:
predicting an overcapacity event within the space during the future time interval.

18. The method of claim 17:
wherein accessing the corpus of sensor data captured by the population of sensor blocks comprises:
accessing a first image, in the corpus of sensor data, captured by a first sensor block, in the population of sensor blocks, the first sensor block:
comprising a first optical sensor defining a field of view intersecting a first region of the space containing a set of desks; and
wherein accessing the predicted total human occupancy count within the space during a future time interval comprises:
extracting a first set of features from the first image;
based on the first set of features:
detecting a first desk in the set of desks; and
detecting a first quantity of humans within a distance threshold of the first desk; and
in response to the first quantity of humans exceeding a human quantity threshold, predicting the predicted total human occupancy count based on the first quantity of humans.

19. A method comprising:
accessing a corpus of occupancy data representing:
a total human occupancy count, in a set of total human occupancy counts, in a representative space during each daily time interval in a set of daily time intervals during a first time period; and
a zone-specific human occupancy count, in a set of zone-specific human occupancy counts, for each zone type, in a set of zone types, within the representative space during each daily time interval in the set of daily time intervals during the first time period;
based on the corpus of occupancy data:
deriving an occupancy distribution function relating zone-specific human occupancy count for each zone type to total human occupancy count within the set of daily time intervals based on the set of total human occupancy counts and the set of zone-specific human occupancy counts; and
during a second time period succeeding the first time period:
accessing a predicted total human occupancy count within a target space during a future time interval;
based on the occupancy distribution function, the predicted total human occupancy count, and the future time interval:
generating a predicted distribution of humans occupying the set of zone types within the target space during the future time interval, the predicted distribution of humans comprising a first count of humans predicted to occupy a first zone type, in the set of zone types, within the target space during the future time interval;
accessing a first occupancy capacity of the first zone type within the target space; and
in response to the first count of humans exceeding the first occupancy capacity of the first zone type within the target space:
predicting an overcapacity event within the target space during the future time interval.

20. The method of claim 19:
further comprising:
accessing a second corpus of occupancy data representing:
a second total human occupancy count, in a second set of total human occupancy counts, in a second representative space during each daily time interval in the set of daily time intervals during the first time period; and
a second zone-specific human occupancy count, in a second set of zone-specific human occupancy counts, for each zone type, in the set of zone types, within the second representative space during each daily time interval in the set of daily time intervals during the first time period; and
wherein deriving the occupancy distribution function relating zone-specific human occupancy count for each zone type to total human occupancy count within the set of daily time intervals comprises deriving the occupancy distribution function relating zone-specific human occupancy count for each zone type to total human occupancy count within the set of daily time intervals further based on a combination of:
the set of total human occupancy counts;
the second set of total human occupancy counts;
the set of zone-specific human occupancy counts; and
the second set of zone-specific human occupancy counts.
